(19) United States
(12) Patent Application Publication
(10) Pub. No.: US 2008/0041257 A1
(43) Pub. Date: Feb. 21, 2008

(54) Device and method for treating lithographic printing plate

(76) Inventor: Gary Ganghui Teng, Northborough, MA (US)

Correspondence Address: GARY GANGHUI TENG, 10 KENDALL DR., NORTHBOROUGH, MA, 01532, US

(21) Appl. No.: 11/859,756

(22) Filed: Sep. 22, 2007

Related U.S. Application Data
(63) Continuation-in-part of application No. 11/787,878, filed on Apr. 17, 2007.
Application No. 11/787,878 is a continuation-in-part of application No. 11/266,817, filed on Nov. 4, 2005, now Pat. No. 7,213,516.

(51) Int. Cl. B41N 1/00; G03F 7/26

(52) U.S. Cl. 101/453; 118/620; 430/302

(57) ABSTRACT

A device as well as method for treating without developing an imagewise exposed lithographic printing plate is disclosed. The device comprises a structure for providing a treating solution to the exposed plate. The exposed plate comprises on a substrate a photosensitive layer having hardened areas and non-hardened areas (for negative plate) or solubilized areas and non-solubilized areas (for positive plate). The non-hardened or solubilized areas of said photosensitive layer is removable with ink and/or fountain solution on a lithographic press. The treatment of the imagewise exposed plate allows one or more enhanced properties for the plate before on-press development, such as improved white light stability, enhanced or formation of visible image, improved hydrophilicity, or improved on-press developability.

### RELATED PATENT APPLICATIONS

This application is a continuation-in-part application of U.S. patent application Ser. No. 11/787,878 filed Apr. 17, 2007 that is a continuation-in-part application of U.S. patent application Ser. No. 11/266,817 filed Nov. 4, 2005, now U.S. Pat. No. 7,213,516.

### FIELD OF THE INVENTION

This invention relates to lithographic printing. More particularly, it relates to a device and method for treating a photosensitive lithographic printing plate after imagewise exposure and before development.

### BACKGROUND OF THE INVENTION

Lithographic printing plates (after process) generally consist of ink-receptive areas (image areas) and ink-repelling areas (non-image areas). During printing operation, an ink is preferentially received in the image areas, not in the non-image areas, and then transferred to the surface of a material upon which the image is to be produced. Commonly the ink is transferred to an intermediate material called printing blanket, which in turn transfers the ink to the surface of the material upon which the image is to be produced.

At the present time, lithographic printing plates (processed) are generally prepared from lithographic printing plate precursors (also commonly called lithographic printing plates) comprising a substrate and a photosensitive coating deposited on the substrate, the substrate and the photosensitive coating having opposite surface properties. The photosensitive coating is usually a photosensitive material, which solubilizes or hardens upon exposure to an actinic radiation, optionally with further post-exposure overall treatment. In positive-working systems, the exposed areas become more soluble and can be developed to reveal the underneath substrate. In negative-working systems, the exposed areas become hardened and the non-exposed areas can be developed to reveal the underneath substrate.

Traditionally, the plate is exposed with an ultraviolet light from a lamp through a separate photomask film having predetermined imaging pattern that is placed between the light source and the plate. Laser sources have been increasingly used to imagewise expose a printing plate that is sensitized to a corresponding laser wavelength, allowing the elimination of the photomask film. Suitable lasers include, for example, infrared lasers (such as laser diode of about 830 nm and NdYAG laser of about 1064 nm), visible lasers (such as frequency-doubled NdYAG laser of about 532 nm and violet laser diode of about 405 nm), and ultraviolet laser (such as ultraviolet laser diode of about 370 mm). Laser sensitive plates generally have higher sensitivity (than conventional plates) because of the limited power of current laser imagers.

Conventionally, the exposed plate is developed with a liquid developer to bare the substrate in the non-hardened or solubilized areas. On-press developable lithographic printing plates have been disclosed in recent years. Such plates can be directly mounted on press after imagewise exposure to develop with ink and/or fountain solution during the initial prints and then to print out regular printed sheets. No separate development process before mounting on press is needed, allowing the reduction of labor and the elimination of hazardous waste. Among the patents describing on-press developable lithographic printing plates are U.S. Pat. Nos. 5,258,263, 5,516,620, 5,561,029, 5,616,449, 5,677,110, 5,811,220, 6,014,929, 6,071,675, and 6,482,571.

While on-press developable plates have the advantage of not requiring a separate wet development process, such plates often have the drawbacks of limited room light stability and weaker visible images. Also, it is hard to design a plate with combined good on-press developability, clean background and good resolution, because, for example, the factors which favor on-press developability or clean background often offset the durability or small dots resolution. It would be desirable if the above drawbacks or problems could be eliminated.

The inventor has found that a simple treatment with a treating solution can be used to modify without developing the exposed on-press developable plate, so as to eliminate the above drawbacks or enhance the performance of the plate, still without requiring a tedious separate development process. Accordingly, a treating device is designed to accomplish such a simple treatment.

### SUMMARY OF THE INVENTION

According to the present invention, there has been provided a lithographic printing plate treating device comprising:
(a) a structure for providing a treating solution;
(b) an exposed lithographic plate comprising on a substrate a photosensitive layer having hardened or solubilized exposed areas and non-hardened or non-solubilized non-exposed areas, the non-hardened (negative-working) or solubilized (positive-working) areas of said photosensitive layer being removable on press with ink and/or fountain solution; and
(c) a transfer means for transporting said exposed plate through said structure to contact said plate with said treating solution without developing the plate.

The transfer means transports the plate through the treating structure as well as the treating device to contact with the treating solution without developing the plate. The treating device does not have a developing means for developing said plate with a regular liquid developer and said device is not (physically and functionally) connected to any regular liquid developing processor for developing said plate. The treated plate can be further developed with ink and/or fountain solution on a lithographic press.

The exposed plate can be prepared from a negative plate or a positive plate by imagewise exposure with a radiation which is actinic to the photosensitive layer. The radiation is preferably a laser having a wavelength selected from 200 to 1200 nm, more preferably a violet or ultraviolet laser (200 to 430 nm) or an infrared laser (750 to 1200 nm), most preferably a violet or ultraviolet laser. The plate is preferably a negative plate.

The treating solution can be any solution capable of causing a chemical or physical change to the plate without developing said plate. Preferably, the treating solution is capable of causing a chemical or physical change to the photosensitive layer or to the substrate surface without developing said photosensitive layer. More preferably, the treating solution is capable of causing a chemical change in the photosensitive layer or on the substrate surface. Most preferably, the treating solution is a deactivating solution capable of deactivating the photosensitive layer, a discoloring solution capable of changing the color of the photosensitive layer primarily or only in the non-hardened or solubilized areas, a hydrophilizing solution capable of enhancing the hydrophilicity of the substrate, and/or a development enhancing solution capable of increasing the ease of on-press development with ink and fountain solution. Particularly suitable is an aqueous solution. Here the term chemical change means a chemical reaction, including a reaction between acid and base.

The structure (also called treating structure) can be any design that can apply the treating solution to at least the photosensitive layer coated side of the plate when transported through said structure; preferably it comprises a tank, a set of spray nozzles, or one or more rollers. The transfer means can be any design which is capable of transferring the exposed plate through the treating structure; preferably it comprises motorized rollers, belts, wheels, sliding bed, or certain combination of them.

The treating device can further comprise a heating unit for heating said plate before passing through said structure for treatment. A pair of squeegee rollers can be installed after the treating structure to squeeze off any excess amount of treating solution from the plate after coming out of the treating structure. The device can further comprise a drying unit for drying off the water and/or any solvent from the treated plate after passing through the structure.

The treating device can be standalone wherein the exposed plate is hand-fed to the treating device, or the treating device can be connected to an imager. Preferably, the treating device is connected to an imager for imagewise exposing a lithographic plate before automatically transporting the exposed plate to said treating device. Both said treating device and said imager can be shielded with covers so that no or substantially no room light or unsafe portion of the room light reaches the plate during the imaging, the transportation from the imager to the treating device, and the treatment at least before being treated. The imager can be connected to a cassette containing at least one plate and capable of automatically feeding said plate from said cassette to said imager for imagewise exposure.

According to another aspect of the present invention, there has been provided a method of processing a lithographic printing plate comprising in order:
(a) providing a lithographic printing plate comprising on a substrate a photosensitive layer capable of hardening (for positive plate) or solubilization (for negative plate) upon exposure to a radiation (preferably a laser) having a % wavelength selected from 200 to 1200 nm; the non-hardened or solubilized areas of said photosensitive layer being removable on press with ink and/or fountain solution;
(b) imagewise exposing said plate with said radiation to cause hardening or solubilization of the photosensitive layer in the exposed areas;
(c) overall applying a treating solution on a treating device to at least the photosensitive layer coated side of said exposed plate without developing said plate; and
(d) developing said treated plate with ink and/or fountain solution on a lithographic press to remove the non-hardened or solubilized areas of said photosensitive layer.

### BRIEF DESCRIPTION OF THE DRAWINGS

FIG. 1 is a diagrammatic cross-sectional view of a lithographic printing plate treating device of the invention comprising a spray unit for supplying a treating solution to an imagewise exposed lithographic printing plate without developing the plate.

FIG. 2 is a diagrammatic cross-sectional view of a lithographic printing plate treating device of the invention comprising a roller for supplying a treating solution to an imagewise exposed lithographic printing plate without developing the plate.

FIG. 3 is a diagrammatic cross-sectional view of a lithographic printing plate treating device of the invention comprising a tank (reservoir) containing a treating solution and a transfer means for passing an imagewise exposed lithographic printing plate through the treating solution in the tank without developing the plate.

FIG. 4 is a diagrammatic cross-sectional view of a lithographic printing plate exposure and treatment assembly of the invention comprising a flatbed laser imager (exposure device) and a treating device; wherein a lithographic printing plate is exposed with the imager and then treated with the treating device.

FIG. 5 is a diagrammatic cross-sectional view of a lithographic printing plate exposure and treatment assembly of the invention comprising a flatbed laser imager and a treating device, as well as a plate cassette for automatically feeding the plate for imaging and a collecting tray for the treated plates; wherein a lithographic printing plate is fed from a plate cassette to the imager for laser exposure, then treated with the treating device, and further transferred to the collecting tray.

FIG. 6 is a diagrammatic cross-sectional view of a lithographic printing plate imaging and treating assembly of the invention comprising a flatbed laser imager and a treating device, as well as a plate cassette for automatically feeding the plate for imaging and a collecting tray for the treated plates; wherein the plates in the cassette, on the imager, and on the treating device are shielded with covers which prevent all or substantially all room light from reaching the plate.

FIG. 7 is a diagrammatic cross-sectional view of a lithographic printing plate imaging and treating assembly of the invention comprising a flatbed laser imager and a treating device, as well as a plate cassette for automatically feeding the plate for imaging and a collecting tray for the treated plates; wherein the imager and the cassette are covered with a set of covers, the treating device is covered with another set of covers, and the imager and the treating device are connected with a covered passage, so that no or substantially no room light reaches the plates while in the cassette, on the imager, and on the treating device.

FIG. 8 is a diagrammatic cross-sectional view of a lithographic printing plate imaging and treating assembly of the invention comprising a flatbed laser imager and a treating device, as well as a plate cassette for automatically feeding the plate for imaging and a collecting tray for the treated plates; wherein the imager, treating device, and the cassette are each covered with a different set of covers which are connected with each other with covered passages.

FIG. 9 is a diagrammatic cross-sectional view of a lithographic printing plate imaging and treating assembly of the invention comprising an internal drum laser imager and a treating device, as well as a plate cassette for automatically feeding the plate for imaging; wherein the cassette is shielded with covers which prevent substantially all of the room light or of the unsafe portion of the room light from reaching the plate.

FIG. 10 is a diagrammatic cross-sectional view of a lithographic printing plate imaging and treating assembly of the invention comprising an internal drum laser imager and a treating device, as well as a plate cassette for automatically feeding the plate for imaging; wherein the cassette, the imager, and the treating device are shielded with covers which prevent substantially all of the room light or of the unsafe portion of the room light from reaching the plates in the cassette, on the imager, and on the treating device.

FIG. 11 is a diagrammatic cross-sectional view of a lithographic printing plate imaging and treating assembly of the invention comprising an external drum laser imager and a treating device, as well as a plate cassette for automatically feeding the plate for imaging.

FIG. 12 is a diagrammatic cross-sectional view of a lithographic printing plate imaging and treating assembly of the invention comprising an external drum laser imager and a treating device, as well as a plate cassette for automatically feeding the plate for imaging and a collecting tray for keeping the treated plates; wherein the cassette, the imager, and the treating device are shielded with covers which prevent substantially all of the room light or of the unsafe portion of the room light from reaching the plates in the cassette, on the imager, and on the treating device.

### DETAILED DESCRIPTION OF THE PREFERRED EMBODIMENTS

In this patent, the term development means selective removal of the non-hardened (for negative plate) or solubilized (for positive plate) areas of the photosensitive layer (without removing the hardened or non-solubilized areas). The term monomer includes both monomer and oligomer, and the term (meth)acrylate includes both acrylate and methacrylate (A monomer means a monomer or an oligomer, and a (meth)acrylate monomer means an acrylate monomer, a methacrylate monomer, or a monomer with both acrylate and methacrylate groups.). The term “comprises a . . . ” means “comprises at least one . . . ”; for example, the term “comprising a monomer” means “comprising at least one monomer.” The term yellow or red light means yellow light red light, or any light with color between yellow and red such as orange light. The term safe light means a light with a certain wavelength range being cut off so that it does not cause hardening (for negative plate) or solubilization (for positive plate) of a certain photosensitive layer at least within a certain amount of time required for certain typical handling and process (such as 2 hours). For most photosensitive layer, a safe light is a yellow or red light. The term white light means a white fluorescent light, white incandescent light, sunlight, or any regular office light. The term “substantially no radiation” means the intensity of the radiation is less than 1% of that for a regular 100-watt incandescent light (for home use, not focused) at a distance of 2 meters. The term “substantial darkness” means the intensity of the radiation is less than 1% of that for a 100-watt incandescent light at a distance of 2 meters. The term “substantially light-tight” means less than 1% of the light can pass through. The term “substantially no room light reaches the plate” means less than 1% of the room light reaches the plate.

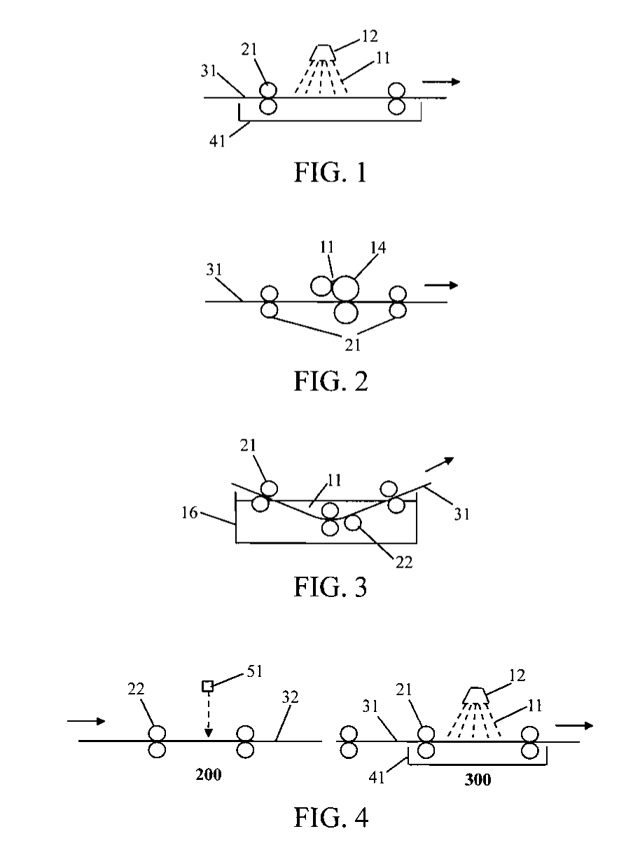

The lithographic printing plate treating device of the invention comprises a structure for providing a treating solution, a transfer means for passing a lithographic printing plate to be in contact with said treating solution, and an imagewise exposed lithographic printing plate that is transferred by said transfer means; wherein said exposed plate comprises on a substrate a photosensitive layer having exposed (hardened or solubilized) areas and non-exposed (non-hardened or non-solubilized) areas. Here the imagewise exposed plate can be a negative plate with hardened areas and non-hardened areas, or a positive plate with solubilized areas and non-solubilized areas. The treating device can be connected to an imaging device for imagewise exposing a plate with a radiation (preferably a laser) before transferring to said treating device. The imager can be connected to a plate cassette for feeding the original plate for imagewise exposure. A collecting tray can be installed around the plate exit of the treating device to collect the treated plate which is not developed. The treating device or the imaging and treatment assembly can be shielded with covers so that no or substantially no room light or unsafe portion of the room light reaches the plate during imaging and/or treatment. Some of the preferred designs of the treating device (including the imaging and treatment assembly) of the instant invention are illustrated in FIGS. 1-12.

FIG. 1 is a diagrammatic cross-sectional view of a lithographic printing plate treating device of the invention comprising a spray unit 12 for supplying a treating solution 11 to an imagewise exposed lithographic printing plate 31 to treat without developing the plate. Said device further comprises a transfer means 21 for transporting said plate through said structure to contact said treating solution with at least the coated side of the plate. A liquid collector 41 is preferably provided to collect any overflowing treating solution. Optionally, the used treating solution in the liquid collector can be recirculated to the spray unit for reuse; a pipe as well as a pump (not shown) can be connected from the tray to the spray unit.

FIG. 2 is a diagrammatic cross-sectional view of a lithographic printing plate treating device of the invention comprising at least one roller 14 for supplying a treating solution 11 to an imagewise exposed lithographic printing plate 31 to treat without developing the plate. The plate is transported by a transfer means 21.

FIG. 3 is a diagrammatic cross-sectional view of a lithographic printing plate treating device of the invention comprising a tank (reservoir) 16 containing a treating solution 11 and a transfer means 21 for passing an imagewise exposed lithographic printing plate 31 through the treating solution in the tank to treat without developing the plate.

FIG. 4 is a diagrammatic cross-sectional view of a lithographic printing plate exposure and treatment assembly of the invention comprising a flatbed laser imager (exposure device) 200 having a laser 51 and a treating device 300 having a spray unit 12 for spraying out a treating solution 11; wherein a lithographic printing plate 31 is exposed with the imager and then transferred by the transfer means 21-22 to the treating device for treatment.

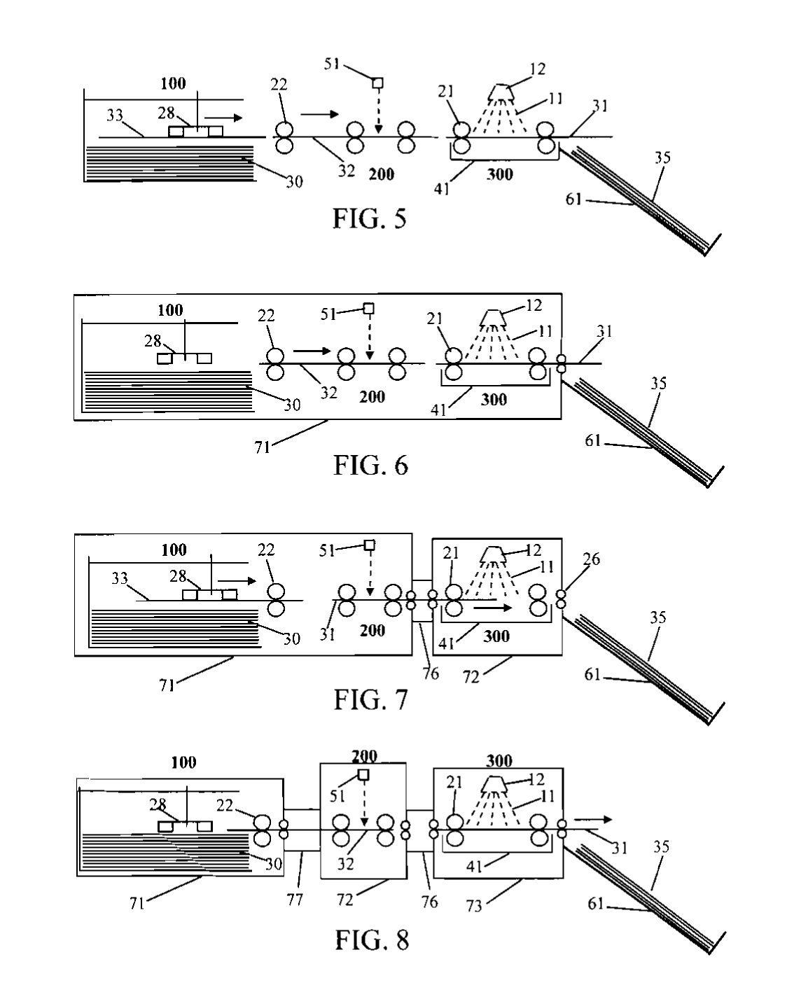

FIG. 5 is a diagrammatic cross-sectional view of a lithographic printing plate exposure and treatment assembly of the invention comprising a flatbed laser imager 200 having a laser 51 and a treating device 300 having a spray unit 12 for spraying out a treating solution 11, as well as a plate cassette 100 having one or more plates 30 for automatically feeding the plate 33 for imaging and a collector 61 for collecting the treated plates 35; wherein a lithographic printing plate 33 is picked up by the feeder 28 from a plate cassette to feed to the imager for laser exposure, then transported by the transfer means 21-22 to the treating device for treatment, and further transported to the collecting tray 61.

FIG. 6 is a diagrammatic cross-sectional view of a lithographic printing plate imaging and treating assembly of the invention comprising a flatbed laser imager 200 and a treating device 300, as well as a plate cassette 100 for automatically feeding the plate for imaging and a collecting tray 61 for the treated plates 35; wherein the plates in the cassette, on the imager, and on the treating device are shielded with covers (or cover) 71 which prevent all or substantially all room light from reaching the plate.

FIG. 7 is a diagrammatic cross-sectional view of a lithographic printing plate imaging and treating assembly of the invention comprising a flatbed laser imager 200 having a laser 51 and a treating device 300 having a spraying unit 12 for applying a treating solution 11, as well as a plate cassette 100 for automatically feeding the plate 33 for imaging and a collecting tray 61 for the treated plates 35; wherein the imager and the cassette are covered with a set of covers 71, the treating device is covered with another set of covers 72, and the imager and the treating device are connected with a covered passage 76, so that no or substantially no room light reaches the plates 33 and 31 while in the cassette, on the imager and on the treating device.

FIG. 8 is a diagrammatic cross-sectional view of a lithographic printing plate imaging and treating assembly of the invention comprising a flatbed laser imager 200 having a laser 51 and a treating device 300 having a spraying unit 12 for applying a treating solution 11, as well as a plate cassette 100 for automatically feeding the plate 31 for imaging and a collecting tray 61 for the treated plates 35; wherein the imager, the treating device, and the cassette are each covered with a different set of covers 71-73 which are connected with each other with covered passages 76-77.

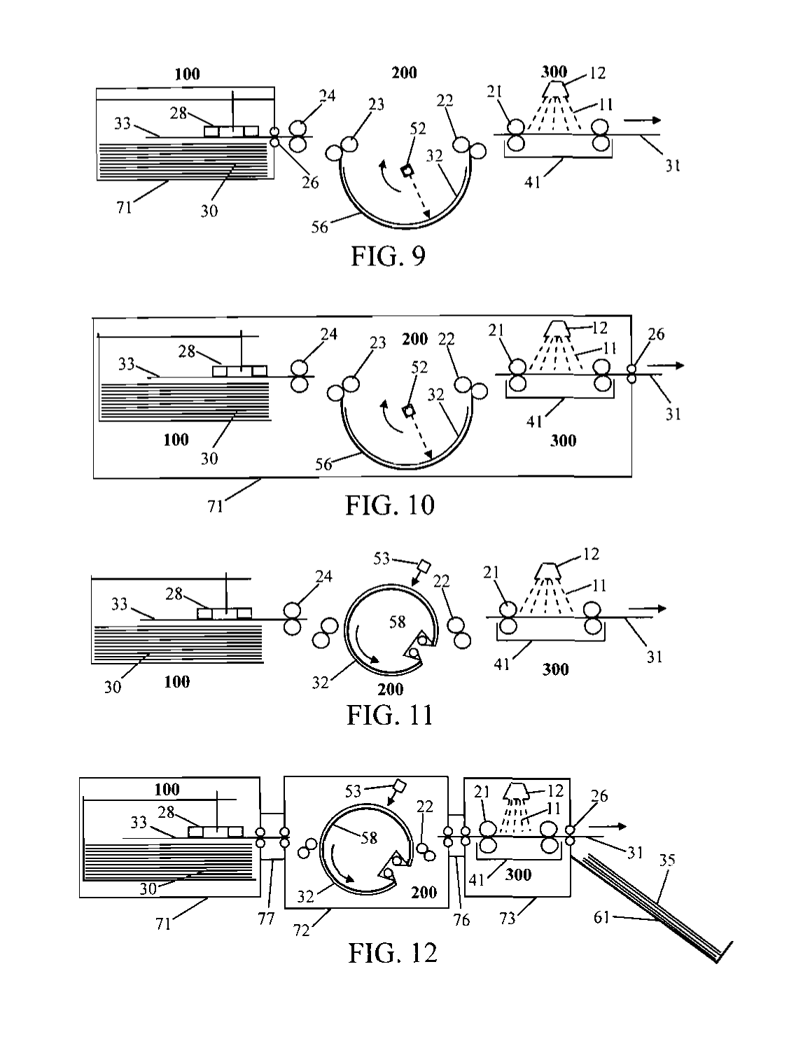

FIG. 9 is a diagrammatic cross-sectional view of a lithographic printing plate imaging and treating assembly of the invention comprising an internal drum laser imager 200 having a laser 52 exposing a plate 32 in a drum 56 and a treating device 300 having a spraying unit 12 for applying a treating solution 11, as well as a plate cassette 100 for automatically feeding the plate 33 for imaging; wherein the cassette is shielded with covers 71 which prevent substantially all of the room light or of the unsafe portion of the room light from reaching the plates 30.

FIG. 10 is a diagrammatic cross-sectional view of a lithographic printing plate imaging and treating assembly of the invention comprising an internal drum laser imager 200 and a treating device 300, as well as a plate cassette 100 for automatically feeding the plate 33 for imaging; wherein the cassette, the imager, and the treating device are shielded with covers 71 which prevent substantially all of the room light or of the unsafe portion of the room light from reaching the plates 30-33 in the cassette, on the imager, and on the treating device.

FIG. 11 is a diagrammatic cross-sectional view of a lithographic printing plate imaging and treating assembly of the invention comprising an external drum laser imager 200 and a treating device 300, as well as a plate cassette 100 for automatically feeding the plate 33 for imaging. The plate 32 mounted on the external drum 58 is exposed with a laser 53.

FIG. 12 is a diagrammatic cross-sectional view of a lithographic printing plate imaging and treating assembly of the invention comprising an external drum laser imager 200 and a treating device 300, as well as a plate cassette 100 for automatically feeding the plate for imaging and a collecting tray 61 for keeping the treated plates; wherein the cassette, the imager, and the treating device are shielded with covers 71-73 and 76-77 which prevent substantially all of the room light or of the unsafe portion of the room light from reaching the plates in the cassette, on the imager and on the treating device as well as during transportation among the cassette, the imager and the treating device.

The structure can be any design which provides the treating solution to the plate (on at least the photosensitive layer coated side). It can be a tank containing the treating solution, a set of spray nozzles which spray out the treating solution, or a roller or rollers which apply the treating solution to the plate. The treating solution can be at room temperature, an elevated temperature, or a below-room temperature; preferably room temperature or an elevated temperature; and more preferably room temperature.

The transfer means transfers the plate through the treating structure to contact with the treating solution without developing the plate. Preferably, said plate is transported by the transfer means through the treating structure and further to the exit of the treating device without being developed. The transfer means can be any design which is capable of transferring the exposed plate through the treating structure. Preferably, the transfer means is a set of rollers, a set of belts, a set of wheels, a sliding bed, or a combination of rollers, belts, wheels, and/or sliding bed, capable of moving the plate through the treating structure, as well as across the treating device. The transfer means is preferably driven by a motor during the treatment operation.

The treating device can further comprise a heating unit for heating said plate before passing through said structure for treatment. The heating unit can be any design, such as forced hot air, hot plate, a radiation heater from the back of the plate such as an infrared lamp, or a radiation heater from the front of the plate (having a photosensitive layer) wherein said radiation has different wavelength from the imaging radiation and does not cause hardening of the photosensitive layer. The plate is preferably heated to at least 50° C., more preferably 70 to 200° C., and most preferably 90 to 150° C.

A pair of squeegee rollers can be installed right after the treating structure to squeeze off any overflowing treating solution from the plate after coming out of the structure. A drying unit can be installed after the treating structure to dry off water and any solvent on the treated plate. Any drying unit capable of drying the plate can be used, such as a drier with forced hot air, forced ambient air, or a radiation. A drying unit supplying forced hot air is preferred. The forced hot air preferably has a temperature of at least 40° C., more preferably 50 to 200° C. Combination of both squeegee rollers and a drying unit with forced hot air on a treating device can be advantageously used for drying the plate, where the treated plate passes through a pair of squeegee rollers followed by passing through a drying unit with forced hot air.

A heater, which is either a heat-generating drying unit or a separate heater installed after the treating structure, may be utilized to heat the plate to an elevated temperature in order to further enhance the performance of the plate. For example, such post heating can cause further crosslinking of the photosensitive layer in the hardened or non-solubilized areas for certain treated plate capable of selectively causing crosslinking of the hardened or non-solubilized areas without significantly effecting the non-hardened or solubilized areas or can further enhance the effect of the treatment (such as causing enhanced color contrast or enhanced hydrophilicity of the substrate) for certain plate. The plate is preferably heated to at least 50° C., more preferably at least 100° C., and most preferably 150 to 300° C. for such post heating.

A radiation source may be installed after the treating structure to overall expose the treated plate with a second radiation in order to further enhance the performance of the plate. For example, such overall exposure can cause further crosslinking of the photosensitive layer in the hardened or non-solubilized areas for certain treated plate capable of selectively causing crosslinking of the hardened or non-solubilized areas without significantly effecting the non-hardened or solubilized areas or can further enhance the effect of the treatment (such as causing enhanced color contrast) for certain plate. The suitable radiation source depends on the particular plate as well as the treating solution, and may be an ultraviolet lamp or an infrared lamp. For example, an ultraviolet lamp (such as a 5,000 watts halogen lamp) can be used to overall expose an imagewise exposed negative plate that has been treated with a deactivating solution which primarily deactivates the non-hardened areas.

The treating device usually does not require a rinse unit. However, water rinse unit may be installed before and/or after the treating structure. For plate with a water soluble or dispersible overcoat, a water rinse unit installed before the treating structure may be utilized to remove the overcoat before the treatment.

For plate with an overcoat, the treating solution can be applied with or without the overcoat being removed first (such as by rinsing with water or an aqueous solution). When the overcoat is not removed before applying the treating solution, the treating solution may penetrate through the overcoat without removing the overcoat, or partially or completely remove the overcoat.

Generally only a single treating solution is applied to the plate. However, two or more different treating solutions can also be applied to the same plate. A treating device can comprise one or more treating structures for supplying one or more treating solutions. Preferably, a treating device has one treating structure supplying one treating solution.

The treating device is preferably shielded with covers so that no or substantially no room light or unsafe portion of the room light reaches the plate when passing through the treating device at least before being treated. The covers prevent or substantially prevent the plate from exposure to the room light or the unsafe portion of the room light, avoiding any undesirable photoreaction to the plate during the treatment process. Depending on the white light sensitivity of the plate and the room lighting, such covers may or may not be required. For plate with high sensitivity to white light (such as violet laser sensitive plate), it is important to have such covers if the treating device is under a white light.

The device is preferably connected to an imager for imagewise exposing a lithographic plate before transporting the exposed plate to said treating device. The combination of an imager and a treating device is also called a lithographic plate imaging and treatment assembly in this application. Preferably, said device and/or said imager are shielded with (non-transparent or yellow or red light-passing-only) covers so that no or substantially no room light or unsafe portion of the room light reaches the plate when being handled and exposed on said imager, when transporting from said imager to said treating device, and/or when passing through the treating device before being treated. More preferably, both said device and said imager, or the whole assembly, are shielded with covers so that no or substantially no room light or unsafe portion of the room light reaches the plate when being exposed on said imager, when transporting from said imager to said treating device, and when passing through the treating device before being treated.

The assembly is preferably connected to a cassette containing at least one plate and capable of automatically feeding said plate from said cassette to said imager for imagewise exposure. The plate cassette can be any design capable of holding at least one plate and capable of feeding one plate at a time to the imager. It is preferably light-tight and capable of holding at least 10 pates.

The laser exposure and treatment of this invention are preferably performed with the plate in substantial darkness or under lightings that will not cause hardening or solubilization of the photosensitive layer at least within a limited time (such as less than 60 minutes) required for handling and processing the plate before being treated. More preferably, these are performed with the plate under a yellow or red light, under a white light for less than 60 minutes (more preferably less than 20 minutes and most preferably less than 10 minutes), or in darkness or substantial darkness. Most preferably, these are performed with the plate under a yellow or red light, or in darkness or substantial darkness. The laser exposure and the treatment can be performed with the plate under the same or different lightings (including darkness). The lighting can be the room light when the plate is open to the room light, or can be the lighting (including darkness) within the covers when the imager and/or treating device is shielded with covers.

During the manual or automatic handling before treatment, the plate is preferably tinder a yellow or red light (such as open to a yellow or red room light or shielded with yellow or red light-passing-only covers), under a white light for less than 60 minutes (more preferably less than 20 minutes and most preferably less than 10 minutes), and/or in darkness or substantial darkness (such as shielded with light-tight or substantially light-tight covers); and more preferably under a yellow or red light and/or in darkness or substantial darkness. During the manual handling before deactivation, the plate is preferably open to a yellow or red room light, or open to a white room light for less than 60 minutes (more preferably less than 20 minutes and most preferably less than 10 minutes); and more preferably open to a yellow or red light. During the automatic handling before deactivation, the plate is preferably shielded with covers (which are substantially light-tight or yellow or red light-passing-only), open to a yellow or red room light, or open to a white room light for less than 60 minutes (more preferably less than 20 minutes and most preferably less than 10 minutes); and more preferably shielded with light-tight or substantially light-tight covers.

Before being treated, the plate is preferably handled and/or stored in darkness or substantial darkness (such as in a light-tight or substantially tight-tight box, wrap or cassette), under white light for limited time (such as less than 30 minutes), or under a yellow or red light (preferably for limited time, such as less than 2 hours). More preferably, the plate is handled and/or stored in darkness or substantial darkness, or under a yellow or red light for limited lime (such as less than 2 hours, preferably less than 1 hour). Most preferably, the plate is stored in darkness, and handled in darkness or substantial darkness or under a yellow or red light. The time allowable under white light or yellow or red light depends on the particular plate; for example, some plates are unsafe under regular office light for even 1 second, some plates are safe under regular office light for up to 10 minutes, some plates are safe under a yellow or red light for up to 60 minutes, and some plates are safe under a yellow or red light for more than 2 hours. Here the term safe means maintaining acceptable performance.

The on-press development can be performed with the plate under any lighting (including darkness), preferably with the plate under a visible light (with the plate open to the white or other visible room light or shielded with substantially light-tight or yellow or red light-passing-only covers), more preferably with the plate open to the room light (of any color), and most preferably with the plate open to a white room light.

The treating solution can be any solution capable of causing a chemical or physical change to the plate without developing said plate. Preferably, the treating solution is capable of causing a chemical or physical change (preferably a chemical change) to the photosensitive layer or to the substrate surface. More preferably, such a treating solution is a deactivating solution capable of deactivating the photosensitive layer, a discoloring solution capable of changing the color of the photosensitive layer primarily or only in the non-hardened or solubilized areas, a hydrophilizing solution capable of enhancing the hydrophilicity of the substrate, a development enhancing solution capable of increasing the on-press developability with ink and/or fountain solution. Even more preferably, the treating solution is a solution comprising a deactivating agent, a discoloring agent, a hydrophilizing agent, or a development enhancer. Most preferably, the treating solution is an aqueous solution comprising a deactivating agent, a discoloring agent, a hydrophilizing agent, or a development enhancer.

The treating solution can be based on water and/or organic solvent as the solvent. Preferably, the treating solution is an aqueous solution. More preferably, the treating solution is an aqueous solution comprising at least 50% by weight of water, most preferably at least 80% by weight of water.

The deactivating agent can be any material that can deactivate the photo hardening (for negative plate) or photo solubilization (for positive plate) capability of the photosensitive layer in the non-hardened or non-solubilized areas, so that the non-hardened (for negative plate) or non-solubilized (for positive plate) photosensitive layer (which is originally capable of hardening or solubilization under a room light) becomes incapable or having reduced rate (preferably incapable) of hardening or solubilization under such room light. The deactivating agent can be a solid, liquid, or gas; preferably a liquid or solid. Either organic or inorganic compound can be used as deactivating agent, such as organic or inorganic acid, base, oxidizer, reducer, or inhibitor. Various deactivating agents have been described in U.S. Pat. No. 7,213,516, and U.S. patent application Ser. Nos. 11/356,911, 11/728,648, 11/787,878, and 11/800,634; the entire disclosures of which are hereby incorporated by reference. The deactivating agent is preferably soluble in water or an organic solvent to form a deactivating solution. More preferably, the deactivating agent is soluble in water and is applied from an aqueous solution. A water-soluble organic solvent, such as ethylene glycol, can be added into the aqueous solution. Certain additives, such as dye, dispersed pigment, bactericide, stabilizer, reducer, thickening agent, and surfactant, can be added. The concentration of the deactivating agent in a deactivating solution is from 0.01 to 70%, more preferably from 0.1 to 30%, and most preferably from 1 to 10% by weight of the solution.

For free radical polymerizable photosensitive layer (which is negative-working), the deactivating agent can be a compound that can react with a component of the free radical initiating system (such as initiator, sensitizing dye, hydrogen donor, or monomer; preferably the initiator, sensitizing dye, or hydrogen donor). For cationic polymerizable photosensitive layer (which is negative-working), the deactivating agent can be a compound that can react with a component of the cationic polymerization system (such as the initiator which is an acid generator, sensitizing dye, or monomer; preferably the initiator or sensitizing dye).

For polymerizable photosensitive layer having an amine group or other acid-reacting group (a group capable of reacting with an acid) in the initiator, sensitizing dye, or hydrogen donor, an acid compound (including organic acid and inorganic acid) can be used as the deactivating agent. Suitable organic acids include, for example, organic compounds having at lease one carboxylic acid group, a sulfonic acid group, or phosphonic acid group. Suitable inorganic acids include, for example, phosphoric acid, boric acid, and hydrochloride acid. Preferred acids are those with moderate acidity, such as organic compounds with at least one carboxylic acid group, phosphoric acid, polyvinyl phosphonic acid, and boric acid. More preferred are water soluble organic acids. Most preferred are water-soluble organic compounds having at least one carboxylic acid group. Suitable organic acids include, for example, citric acid, acetic acid, salicylic acid, glycolic acid, malic acid, and lactic acid. Citric acid and malic acid are particularly suitable because they are widely used natural organic acids and are non-hazardous to the environment. The acid is preferably applied as an aqueous solution to deactivate the photosensitive layer. When strong acid (such as hydrochloric acid) is used as deactivating agent, it is preferably diluted to low concentration (such as less than 0.5%, preferably less than 0.1% by weight) in an aqueous solution to apply to the plate so that it does not damage the plate or cause safety problem. The acidic deactivating solution preferably has a pH of from 0.1 to 6.5, more preferably from 0.5 to 5.0, and most preferably from 1.0 to 4.0. The acidic deactivating solution preferably has a concentration of from 0.01 to 70%, and more preferably from 0.05 to 30% by weight of the solution. The aqueous acidic deactivating solution based on organic acid preferably has a concentration of from 0.1 to 70%, more preferably from 0.5 to 30%, and most preferably from 2 to 10% by weight of the solution.

An alkaline compound can also be used as the deactivating agent for certain negative plates with free radical or cationic polymerizable or other acid crosslinkable photosensitive layers because it can react with certain free radical initiating system (such as initiator, sensitizing dye, or hydrogen donor), certain cationic initiating system (such as initiator which is an acid generator, or sensitizing dye), and other acid crosslinkable systems (such as negative-working diazonaphthoquinone systems). For example, an alkaline compound can react with an ionic initiator such as an onium salt, an ionic sensitizing dye such as a cyanine dye, or a hydrogen donor having carboxylic acid or thiol group; and can also neutralize with a cationic initiator which is an acid generator. Suitable alkaline compounds include, for example, sodium silicate, potassium silicate, sodium carbonate sodium hydroxide, and organic amines. Preferred alkaline compounds are water-soluble compounds with moderate basicity, such as sodium silicate, potassium silicate, ammonium hydroxide, and amines. More preferred amines are organic amines, including polymeric amines. Suitable water-soluble amines include regular amine compounds such as triethylamine, triethanolamine, 2-amino-2-methyl-1-propanol, tris(hydroxymethyl)aminomethane and N-methyl-2-pyrrolidone, and polymeric amines such as polyethyleneamine. The alkaline compound is preferably applied as an aqueous solution to deactivate the photosensitive layer. When strong base (such as sodium hydroxide) is used as deactivating agent, it is preferably diluted to low concentration (such as less than 0.5%, preferably less than 0.1% by weight) in an aqueous solution so that it does not damage the plate or cause safety problem. The alkaline deactivating solution preferably has a pH of from 7.5 to 13.5, more preferably from 8.0 to 12.0, and most preferably from 9.0 to 11.0. The alkaline deactivating solution preferably has a concentration of from 0.01 to 70%, and more preferably from 0.05 to 30% by weight of the solution. The aqueous alkaline deactivating solution based on organic amine preferably has a concentration of from 0.1 to 70%, more preferably from 0.5 to 30%, and most preferably from 2 to 10% by weight of the solution.

A free radical inhibitor can be used as the deactivating agent for plates with a free radical polymerizable photosensitive layer. Examples of suitable free radical inhibitors include methoxyhydroquinone, hydroquinone, 2,6-di-tert-butyl-4-methylphenol, polyvinylphenol, other compounds with at least one phenol group, and various commercial free radical stabilizer. Preferably, the inhibitor is dissolved in water or a water-solvent mixture (containing water and a water soluble organic solvent) to form an aqueous deactivating solution for applying to the plate. The deactivating solution based on a free radical inhibitor preferably has a concentration of from 0.1 to 70%, more preferably from 0.5 to 30%, and most preferably from 2 to 10% by weight of the solution.

For positive plate with the photosensitive layer capable of solubilization upon exposure to a radiation as well as under a room light through the mechanism of acid catalyzed decomposition (such as positive plates based on a novalac resin and an acid generator), an alkaline compound can be used as the deactivating agent. Suitable alkaline compounds include, for example, sodium silicate, potassium silicate, sodium carbonate, sodium hydroxide, and organic amines. Preferred alkaline compounds are water-soluble compounds with moderate basicity, such as sodium silicate, potassium silicate, ammonium hydroxide, and amines. More preferred amines are organic amines, including polymeric amines. Suitable water-soluble amines include regular amine compounds such as triethylamine, triethanolamine, 2-amino-2-methyl-1-propanol, tris(hydroxymethyl)aminomethane and N-methyl-2-pyrolidone, and polymeric amines such as polyethyleneamine. The alkaline compound is preferably applied as an aqueous solution to deactivate the photosensitive layer. The alkaline deactivating solution preferably has a pH of from 7.5 to 13.5, more preferably from 8.0 to 12.0, and most preferably from 9.0 to 11.0. The alkaline deactivating solution preferably has a concentration of from 0.01 to 70%, and more preferably from 0.05 to 30% by weight of the solution. The aqueous alkaline deactivating solution based on organic amine preferably has a concentration of from 0.1 to 70%, more preferably from 0.5 to 30%, and most preferably from 2 to 10% by weight of the solution.

The discoloring agent suitable for this invention can be any material that is capable of changing the color of the photosensitive layer primarily or only in the non-hardened areas, with less or no color change in the hardened areas. Preferably, the discoloring agent suitable for this invention is a material that is capable of reacting with a dye or latent dye in the photosensitive layer to cause color change (including turning on or turning off of color). The discoloring agent is preferably dissolved in water and/or an organic solvent to form a discoloring solution. It is preferably soluble in water and is dissolved in water to form an aqueous discoloring solution. The discoloring agent can be a solid, liquid, or gas; preferably a liquid or solid. Various additives, such as surfactant, stabilizer, bactericide, defoamer, dye, cosolvent, pigment, and thickener can be added in the discoloring solution. Depending on the photosensitive layer as well as its dye or pigment system, the discoloring agent can be different.

The discoloring solution is preferably capable of diffusing into the non-hardened (for negative plate) or solubilized (for positive plate) areas more efficiently than into the hardened or non-solubilized areas, the application of such discoloring solution causes color change primarily or only in the non-hardened or solubilized areas, with less or no color change in the hardened or non-solubilized areas. Here, the term that the discoloring solution is capable of diffusing into the non-hardened areas of the photosensitive layer more efficiently than into the hardened areas means that more discoloring solution can diffuse into the non-hardened areas of the photosensitive layer while less or no discoloring solution can diffuse into the hardened areas of the photosensitive layer.

For photosensitive layer comprising a visible dye capable of discoloration, the discoloring agent can be any compound capable of discoloring the dye. Application of a discoloring solution containing the discoloring agent changes the color of the dye primarily or only in the non-hardened (for negative plate) or solubilized (for positive plate) areas, with less or no color change in the hardened or non-solubilized areas. Preferably, the color change is color reduction. For example, an imagewise exposed photosensitive layer comprising a crystal violet can be discolored with a hydrochloric acid aqueous solution to reduce the blue color in the non-hardened (for negative plate) or solubilized (for positive plate) areas, with the hardened or non-solubilized areas remaining substantially the original blue color.

For photosensitive layer comprising a latent dye, the discoloring agent can be any compound capable of turning on the color of the latent dye. The application of said discoloring agent from a discoloring solution partially or completely turns on the color of the latent dye primarily or only in the non-hardened (for negative plate) or solubilized (for positive plate) areas, with less or no color change in the hardened or non-solubilized areas. Examples of such system include a photosensitive layer having an acid sensitive latent dye and a discoloring solution which is an acid aqueous solution, and the application of such acid solution to the imagewise exposed plate turns on the color primarily or only in the non-hardened or solubilized areas, with less or no color turning on in the hardened or non-solubilized areas. Various latent dyes can be used, such as leuco crystal violet, leucomalachite green, azobenzene, 4-phenylazodiphenylamine, and methylene blue dyes.

For photosensitive layer having a visible dye capable of changing color (preferably turning off color) or a latent dye capable of turning on color upon contact with an acid, an acid solution can be used as the discoloring solution. Preferably, an acid aqueous solution is used as the discoloring solution. The acid can be an organic acid or inorganic acid. Suitable organic acids include, for example, organic compounds having at lease one carboxylic acid group, a sulfonic acid group, or phosphonic acid group. Suitable inorganic acids include, for example, phosphoric acid, boric acid, and hydrochloride acid. Preferred acids are those with moderate acidity, such as organic compounds with at least one carboxylic acid group, phosphoric acid, polyvinyl phosphonic acid, and boric acid. More preferred are water soluble organic acids. Most preferred are water-soluble organic compounds having at least one carboxylic acid group. Solid acid (such as citric acid) is particular useful because it does not evaporate from the photosensitive layer. Suitable organic acids include, for example, citric acid, acetic acid, salicylic acid, glycolic acid, malic acid, and lactic acid. Citric acid and malic acid are particularly suitable because they are widely used natural organic acids and are non-hazardous to the environment. The acid is preferably applied as an aqueous solution to discolor the photosensitive layer. When strong acid (such as hydrochloric acid) is used as discoloring agent, it is preferably diluted to low concentration (such as less than 0.5%, preferably less than 0.1% by weight) in an aqueous solution to apply to the plate so that it does not damage the plate or cause safety problem. The acidic discoloring solution preferably has a pH of from 0.1 to 6, more preferably from 0.5 to 4.0, and most preferably from 1.0 to 3.0. The acidic discoloring solution preferably has a concentration of from 0.01 to 70%, and more preferably from 0.05 to 30% by weight of the solution. The aqueous acidic discoloring solution based on organic acid preferably has a concentration of from 0.1 to 70%, more preferably from 0.5 to 30%, and most preferably from 2 to 10% by weight of the solution.

For photosensitive layer having a visible dye capable of changing color (preferably turning off color) or a latent dye capable of turning on color upon contact with a base, an alkaline solution can be used as the discoloring solution. Preferably an alkaline aqueous solution is used as the discoloring solution. Suitable alkaline compounds include, for example, sodium silicate, potassium silicate, sodium carbonate sodium hydroxide, and organic amines. Preferred alkaline compounds are water-soluble compounds with moderate basicity, such as sodium silicate, potassium silicate, ammonium hydroxide, and amines. More preferred amines are organic amines, including polymeric amines. Suitable water-soluble amines include regular amine compounds such as triethylamine, triethanolamine, 2-amino-2-methyl-1-propanol, tris(hydroxymethyl)aminomethane and N-methyl-2-pyrrolidone, and polymeric amines such as polyethyleneamine. The alkaline compound is preferably applied as an aqueous solution to discolor the photosensitive layer. When strong base (such as sodium hydroxide) is used as discoloring agent, it is preferably diluted to low concentration (such as less than 0.5%, preferably less than 0.1% by weight) in an aqueous solution so that it does not damage the plate or cause safety problem. The alkaline discoloring solution preferably has a pH of from 8 to 13.5, more preferably from 8.5 to 12.0, and most preferably from 9.0 to 11.0. The alkaline discoloring solution preferably has a concentration of from 0.01 to 70%, and more preferably from 0.05 to 30%, by weight of the solution. The aqueous alkaline discoloring solution based on organic amine preferably has a concentration of from 0.1 to 70%, more preferably from 0.5 to 30%, and most preferably from 2 to 10% by weight of the solution.

For a photosensitive layer comprising a dispersed pigment, the discoloring solution can be any material capable of causing flocculation of the dispersed pigment primarily or only in the non-hardened (for negative plate) or solubilized (for positive plate) areas, with less or no color change in the hardened or non-solubilized areas. Such a discoloring solution is also called flocculating solution. Here the term flocculation means becoming non-dispersed, aggregated, or insolubilized from a dispersed or solubilized system. Preferably, the flocculating solution is a solution (including blend of solvents, with water also being considered a solvent) capable of causing flocculation (or aggregation) of the dispersed pigment in the photosensitive layer upon diffusing into it and capable of diffusing into the non-hardened or solubilized areas of the photosensitive layer more efficiently than into the hardened or non-solubilized areas. More preferably, the flocculating solution diffuses into the photosensitive layer in the non-hardened or solubilized areas to flocculate the pigment without completely dissolving the photosensitive layer so that the photosensitive layer in the non-hardened or solubilized areas does not flow around. Any pigment can be used, including organic pigment such as copper phthalocyanine and other phthalocyanine pigments, and inorganic pigment such as iron oxide and copper carbonate. The pigment is dispersed as fine particles in the photosensitive layer, usually with certain pigment dispersant or polymer, so as to have good color strength. The flocculating solution is preferably capable of swelling (without completely dissolving) the photosensitive layer in the non-hardened or solubilized areas but incompatible with (causing flocculation of) the pigment dispersion. A compound capable of causing or helping the flocculation (such as by physical interaction or chemical reaction with the dispersant) can be used in the flocculating solution.

For a photosensitive layer comprising a visible dye capable of flocculation, the discoloring solution (also called flocculating solution here) can be any solution capable of causing flocculation of such dye primarily or only in the non-hardened (for negative plate) or solubilized (for positive plate) areas, with less or no color change in the hardened or non-solubilized areas. The visible dye is insoluble in the non-hardened or solubilized photosensitive layer soaked with such flocculating solution and is capable of flocculating into less or different colored (preferably less colored) aggregates in the photosensitive layer. Preferably, the flocculating solution is capable of causing flocculation of the visible dye in the photosensitive layer upon diffusing into it and capable of diffusing into the non-hardened or solubilized areas of the photosensitive layer more efficiently than into the hardened or non-solubilized areas. More preferably, the flocculating solution is capable of diffusing into the photosensitive layer in the non-hardened or solubilized areas without completely dissolving the photosensitive layer so that the photosensitive layer in the non-hardened or solubilized areas does not flow around.

The hydrophilizing agent can be any compound capable of enhancing the hydrophilicity of the substrate. Preferably, such hydrophilizing agent is an acid or base, more preferably an acid. Suitable acid compounds include organic compounds with at least 1 carboxylic acid groups, polymers with phosphonic acid groups, and phosphoric acid. Particularly suitable acid compounds include citric acid, acetic acid, salicylic acid, glycolic acid, malic acid, lactic acid, phosphoric acid, and polyvinyl phosphonic acid. The hydrophilizing agent is preferably dissolved in water and/or an organic solvent, more preferably in water, to form a hydrophilizing solution for applying to the plate.

The development enhancer can be any compound capable of enhancing the developability of the photosensitive layer in ink and/or fountain solution. Preferably, such development enhancer is an organic compound capable of enhancing the developability of the photosensitive layer in ink and/or fountain solution. More preferably, such development enhancer is a liquid organic compound capable softening the photosensitive layer. The water soluble liquid organic compound suitable as development enhancer preferably has a boiling point of at least 150° C., more preferably at least 200° C., and most preferably at least 250° C. Suitable development enhancers include, for example, polyethylene glycol, glycerin, methoxypropanol, diethyleneglycol, triethyleneglycol, and various nonionic surfactants. The development enhancer is preferably dissolved in water and/or an organic solvent, more preferably in water, to form a development enhancing solution for applying to the plate. Preferably, the application of the development enhancer increases the ease of developing the plate, so that the roll up impressions (the number of rotations of the plate cylinder between engaging the inking roller and completely cleaning up the background of the plate) is reduced by at least 5 impressions, more preferably at least 10 impressions, and most preferably at least 20 impressions due to the application of the development enhancer. For example, for an untreated plate originally requiring 30 roll up impressions (of the rotations of the plate cylinder) to achieve clean background, the same plate treated with a development enhancer only requires at most 25 roll up impressions (preferably at most 20 impressions, more preferably at most 10 impressions) to achieve clean background.

The treating solution should be capable of enhancing a certain aspect of the performance of the plate. Preferably, the treating solution is capable of enhancing more than one aspects of the performance of the imagewise exposed plate, such as enhancing both the white light stability (by deactivating the photosensitive layer) and the visible image contrast (by discoloration primarily or only in the non-hardened or solubilized areas). More preferably, the treating solution is capable of enhancing the white light stability (by deactivation), the image contrast (by discoloration primarily or only in the non-hardened or solubilized areas), the hydrophilicity of the substrate, and the developability of the photosensitive layer. The treating solution capable of two or more functions (such as both deactivation and discoloration) can comprise 2 separate components (such as a deactivating agent and a discoloring agent), can comprise the same component capable of both functions (such as a deactivating agent which is also a discoloring agent), or can comprise both a component with two or more functions and a component with only single function. Preferably, the treating solution comprises at least one component which is capable of two or more functions (such as both deactivating the photosensitive layer and hydrophilizating the substrate). Examples of multifunctional treating agents include an acid compound (such as citric acid, applied from an aqueous solution) which is capable of deactivation, discoloration, and hydrophilization for certain plates. Examples of single-functional treating agents include a water soluble organic solvent (such as triethyleneglycol, applied from an aqueous solution) which is capable of enhancing the on-press developability of the photosensitive layer.

For the plate of this application, at least the hardened (for negative plate) or non-solubilized (for positive plate) areas of the photosensitive layer exhibit an affinity or aversion substantially opposite to the affinity or aversion of the substrate to at least one printing liquid selected from the group consisting of ink and an adhesive fluid for ink (including both plates with non-phase-switchable photosensitive layer and plates with phase-switchable photosensitive layer). Preferably, the photosensitive layer exhibits an affinity or aversion substantially opposite to the affinity or aversion of the substrate to at least one printing liquid selected from the group consisting of ink and an adhesive fluid for ink (as for plates with non-phase-switchable photosensitive layer, which can be wet plate or waterless plate). More preferably, the plate has a hydrophilic substrate and an oleophilic photosensitive layer (as for wet plate with non-phase-switchable photosensitive layer). An adhesive fluid for ink is a fluid that repels ink. Fountain solution is the most commonly used adhesive fluid for ink. A wet plate is printed on a wet press equipped with both ink and fountain solution, while a waterless plate is printed on a waterless press equipped with ink.

Usually, as for most printing plates described in the literature, the photosensitive layer exhibits an affinity or aversion substantially opposite to the affinity or aversion of the substrate to at least one printing liquid selected from the group consisting of ink and an adhesive fluid for ink, and does not switch its affinity or aversion upon exposure to an actinic radiation. However, certain photosensitive layer exhibits substantially the same affinity or aversion as the substrate and is capable of switching to opposite affinity or aversion upon exposure to a radiation (with or without further treatment such as on-press development with ink and/or fountain solution), as described in U.S. Pat. Nos. 6,331,375, 5,910,395, 6,720,464, and 6,136,503. Both non-phase-switchable photosensitive layer and phase-switchable photosensitive layer can be used for the current invention. Preferred is a non-phase-switchable photosensitive layer (coated on a substrate with opposite affinity or aversion). More preferred is an oleophilic photosensitive layer (coated on a hydrophilic substrate).

The substrate employed in the lithographic plates of this invention can be any lithographic support. Such a substrate may be a metal sheet, a polymer film, or a coated paper. Aluminum (including aluminum alloy) sheet is a preferred metal support. Particularly preferred is an aluminum support that has been grained and anodized (with or without deposition of a barrier layer). Polyester film is a preferred polymeric support. A surface coating may be coated to achieve desired surface properties. For wet plate, the substrate should have a hydrophilic surface (for oleophilic photosensitive layer) or oleophilic surface (for hydrophilic photosensitive layer); preferably, a wet lithographic plate has a hydrophilic substrate and an oleophilic photosensitive layer. For waterless plate, the substrate should have an oleophilic surface (for oleophobic photosensitive layer) or oleophobic surface (for oleophilic photosensitive layer).

Particularly suitable hydrophilic substrate for a wet lithographic plate is an aluminum support that has been grained and anodized, preferably with further hydrophilic treatment. Surface graining can be achieved by mechanical graining or brushing, chemical etching, and/or AC electrochemical graining. The grained aluminum is typically treated with a basic or acidic solution to remove the smut, and then subjected to an electrochemical anodization process utilizing an acid such as sulfuric acid and/or phosphoric acid. The roughened and anodized aluminum surface can be further treated with a hydrophilic material to form a hydrophilic barrier layer. Suitable hydrophilic materials include metal silicate such as sodium silicate, phosphate fluoride (formed from a solution containing sodium dihydrogen phosphate and sodium fluoride), phosphoric acid and hydrophilic polymer such as polyvinyl phosphonic acid, polyacrylamide, polyacrylic acid, polybasic organic acid, copolymers of vinyl phosphonic acid and acrylamide. Polyvinyl phosphonic acid and its copolymers are preferred hydrophilic polymers. The hydrophilic material can be formed on the aluminum surface by thermal or electrochemical method. By thermal method, the grained and anodized aluminum passes through or is immersed for a certain time in a solution containing the hydrophilic material at a certain temperature including elevated and room temperature. By electrochemical method, a DC or AC electricity is applied to the aluminum while passing through or immersed in the solution containing the hydrophilic material. Processes for surface graining, anodization, and hydrophilic treatment of aluminum in lithographic printing plate application are well known in the art, and examples can be found in U.S. Pat. Nos. 2,714,066, 4,153,461, 4,399,021, 5,368,974, and 6,555,205.

For preparing lithographic printing plates of the current invention, any photosensitive layer is suitable which is capable of hardening (for negative plate) or solubilization (for positive plate) upon exposure to a radiation having a wavelength selected from 200 to 1200 nm, and on-press removable with ink and/or fountain solution in the non-hardened or solubilized areas. Such photosensitive layer is preferably soluble or dispersible in ink and/or fountain solution in the non-hardened or solubilized areas. Here hardening means becoming insoluble and non-dispersible in ink and/or fountain solution (negative-working); and solubilization means becoming soluble or dispersible in ink and/or fountain solution (positive-working). In this invention, hardening or solubilization can be achieved through any means. Preferably, hardening is achieved through crosslinking or polymerization of polymers and/or monomers, and solubilization is achieved through decomposition of polymer and/or compound. The radiation can be a conventional light such as ultraviolet light from a lamp (which usually requires a photomask), or can be a laser (which directly images according to digital imaging information). Preferably, the photosensitive layer is sensitive to a laser and exposed with such laser. The photosensitive layer preferably has a coverage of from 100 to 4000 mg/m², and more preferably from 400 to 2000 mg/m².

Photosensitive layer suitable for the current invention may be formulated from various photosensitive materials to achieve on-press developability with ink and/or fountain solution. The composition ratios (such as monomer to polymer ratio) are usually different from conventional plates designed for development with a regular liquid developer. Various additives may be added to, for example, allow or enhance on-press developability. Such additives include surfactant, plasticizer, water soluble polymer or small molecule, and ink soluble polymer or small molecule. Addition of nonionic surfactant is especially helpful in making the photosensitive layer dispersible in and on-press developable with ink and/or fountain solution. Various additives useful for conventional photosensitive layer can also be used. These additives include pigment, dye, exposure indicator, and stabilizer.

Photosensitive materials useful for negative-working wet plates of this invention include, for example, photopolymers (comprising acrylic monomers, polymeric binders, and photoinitiators), light-sensitive compositions comprising polyfunctional vinyl ethers or epoxy monomers and cationic photoinitiators, and polycondensation products of diazonium salts.

Photosensitive materials useful for positive-working wet plates of this invention include, for example, diazo-oxide compounds such as benzoquinone diazides and naphthoquinone diazides, and positive-working novalac systems such as a thermosensitive layer based on combination of a novalac resin and an infrared absorbing dye.

Photosensitive materials useful for wet plates of this invention include, for example, photosensitive compositions comprising an oleophilic polymeric binder, a polymerizable monomer, an initiator, and optionally a sensitizing dye.

Photosensitive oleophobic materials useful for waterless plates of this invention include, for example, compositions comprising polymers having perfluoroalkyl groups and crosslinkable terminal groups, and compositions comprising polysiloxane and crosslinkable resins.

Infrared laser sensitive (also called thermosensitive) materials useful for thermosensitive lithographic plates of this invention include, for example, thermosensitive compositions comprising a polymerizable monomer, an initiator, an infrared absorbing dye, and optionally a polymeric binder.

Visible or ultraviolet light sensitive materials useful for visible or ultraviolet laser sensitive plates of this invention include, for example, photosensitive compositions comprising a polymerizable monomer, an initiator, a visible or ultraviolet light sensitizing dye, and optionally a polymeric binder. A hydrogen donor is preferably added to accelerate the polymerization.

Polymeric binder for the photosensitive layer of this invention can be any solid film-forming polymer. The polymer may or may not have (meth)acrylate groups or other ethylenic groups (such as allyl groups). Examples of suitable polymers include (meth)acrylic polymers and copolymers (such as polybutylmethacrylate, polyethylmethacrylate, polymethylmethacrylate, polymethylacrylate, butylmethacrylate/methylmethacrylate copolymer, methylmethacrylate/methylmethacrylic acid copolymer, polyallylmethacrylate, and allylmethacrylate/methacrylic acid copolymer), polyvinyl acetate, polyvinyl butyrate, polyvinyl chloride, styrene/acrylonitrile copolymer, styrene/maleic anhydride copolymer and its partial ester, nitrocellulose, cellulose acetate butyrate, cellulose acetate propionate, vinyl chloride/vinyl acetate copolymer, butadiene/acrylonitrile copolymer, and polyurethane binder. Polymeric binders having polymer backbone with recurring units having pendant poly(alkylene glycol) side chains are particularly useful for on-press developable plates of this invention. The polymeric binder suitable for the photosensitive layer of this invention has a weight average molecular weight of at least 5,000, preferably from 10,000 to 1,000,000, more preferably from 20,000 to 500,000, and most preferably from 50,000 to 200,000 Dalton. It is noted that polymeric compounds with weight average molecular weight of less that 5,000 can also be added in the photosensitive layer of this invention; however, in order to avoid confusion, such compounds are not considered as polymeric binder and are called oligomer (without or with ethylenic groups) in this application (oligomers having ethylenic groups are also included in the definition of monomers in this application).

Suitable free-radical polymerizable monomers include any monomer or oligomer with at least one ethylenically unsaturated group. Such monomers include monofunctional, difunctional, and multifunctional (meth)acrylate monomers or oligomers, such as (meth)acrylate esters of ethylene glycol, trimethylolpropane, pentaerythritol, ethoxylated ethylene glycol and ethoxylated trimethylolpropane; multifunctional urethanated (meth)acrylate; epoxylated (meth)acrylate; and oligomeric amine (meth)acrylates. The monomers can be urethane (meth)acrylate, or non-urethane (meth)acrylate. Combination of both urethane (meth)acrylate and non-urethane (meth)acrylate monomers can be used. The monomers preferably has at least 3 (meth)acrylate groups, more preferably at least 4 (meth)acrylate groups, even more preferably at least 5 (meth)acrylate groups, and most preferably at least 6 (meth)acrylate groups. However monofunctional or difunctional (meth)acrylate monomer can be added into the photosensitive layer having multifunctional (meth)acrylate monomers; the total amount of such monofunctional or difunctional monomers is preferably less than 50% by weight of the total monomers, more preferably less than 30%, and most preferably less than 10%. Acrylate monomer is preferred over methacrylate monomer because of the faster photospeed of acrylate group over methacrylate group. The monomer has a molecular weight of less than 5,000, preferably from 100 to 3,000, more preferably from 200 to 2,000, and most preferably from 300 to 1,500 Dalton.

Urethane (meth)acrylate monomers include any compounds having at least one urethane linkage (—NHCOO—) and at least one (meth)acrylate group. Preferred urethane (metha)acrylate monomers are those with at least 3 (meth)acrylate groups, more preferably at least 4 (meth)acrylate groups, even more preferably at least 5 (meth)acrylate groups, and most preferably at least 6 (meth)acrylate groups. Urethane (meth)acrylate monomer is usualy formed by reacting a compound having at least one isocyanate group with a (meth)acrylate compound having a hydroxy group. Urethane monomer with 2 or more (meth)acrylate groups are usually formed from a compound having one or more isocyanate groups and a (meth)acrylate compound having a hydroxy group and one or more (meth)acrylate groups. For example, a tetrafunctional urethane (meth)acrylate monomer can be formed from a compound having one hydroxy group and 2 (meth)acrylate groups with a bifunctional isocyanate compound. Suitable isocyanate compounds include, for example, aromatic diisocyanate such as p-phenylene diisocyanate 2,4-tolylene diisocyanate, 2,6-tolylene diisocyanate, 4,4′-diphenylmethane diisocyanate, naphthalene-1,5-diisocyanate and tolydine diisocyanate; aliphatic diisocyanate such as hexamethylene diisocyanate, lysinemethyl ester diisocyanate, 2,4,4-trimethylhexamethylene diisocyanate and dimer acid diisocyanate; alicyclic diisocyanate such as isophorone diisocyanate, and 4,4′-methylenebis(cyclohexylisocyanate); aliphatic diisocyanate having an aromatic ring such as xylylene diisocyanate; triisocyanate such as lysine ester triisocyanate, 1,6,11-undecane triisocyanate, 1,8-diisocyanate-4-isocyanatemethyloctane, 1,3,6-hexamethylene triisocyanate, bicycloheptane triisocyanate, tris(isocyanate phenylmethane) and tris(isocyanatephenyl)thiophosphate; and polyisocyanate formed from condensation of three or more diisocyanate compounds such as 2,4-tolylene diisocyanate isocyanurate trimer, 2,4-tolylene diisocyanate-trimethylolpropane adduct, 1,6-hexanediisocyanate isocyanurate trimer. Suitable (meth)acrylate compounds with one hydroxy group include pentaerythritol tri(meth)acrylate, dipentaerythritol penta(meth)acrylate, ditrimethylolpropane tri(meth)acrylate and pentaerythritol di(meth)acrylate monostearate. Various urethane (meth)acrylate monomers are described in U.S. Pat. No. 6,232,038 and U.S. Pat. Pub. No. 2002/0018962, and can be used as the urethane (meth)acrylate monomers of this instant invention. Among the urethane (meth)acrylate monomers, urethane acrylate monomer is preferred. Either aromatic urethane (meth)acrylate monomer (which contains at least one aromatic group in the molecule) or aliphatic urethane (meth)acrylate monomer (which does not contain any aromatic group in the molecule) or both can be used in a photosensitive layer of this invention.

Suitable non-urethane (meth)acrylate monomers can be any (meth)acrylate monomers without urethane linkage (—NHCOO—) in the molecule. Suitable non-urethane (meth)acrylate monomers include, for example, trimethylolpropane triacrylate, pentaerythritol tetra(meth)acrylate, dipentaerythritol penta(meth)acrylate, dipentaerythritol hexa(meth)acrylate, di(trimethylolpropane) tetra(meth)acrylate. Among the non-urethane (meth)acrylate monomers, non-urethane acrylate monomer is preferred.

Suitable free-radical initiators include, for example, the derivatives of acetophenone (such as 2,2-dimethoxy-2-phenylacetophenone, and 2-methyl-1-[4-(methylthio)phenyl]-2-morpholino propan-1-one), onium salts such as diaryliodonium hexafluoroantimonate, diaryliodonium hexafluorophosphate, diaryliodonium triflate, (4-(2-hydroxytetradecyl-oxy)phenyl)phenyliodonium hexafluoroantimonate, (4-octoxyphenyl)phenyliodonium hexafluoroantimonate, bis(4-t-butylphenyl)iodonium hexafluorophosphate, triarylsulfonium hexafluorophosphate, triarylsulfonium p-toluenesulfonate, (3-phenylpropan-2-onyl) triaryl phosphonium hexafluoroantimonate and N-ethoxy(2-methyl)pyridinium hexafluorophosphate, and the onium salts as described in U.S. Pat. Nos. 5,955,238, 6,037,098 and 5,629,354; borate salts such as tetrabutylammonium triphenyl(n-butyl)borate, tetraethylammonium triphenyl(n-butyl)borate, diphenyliodonium tetraphenylborate, and triphenylsulfonium triphenyl(n-butyl)borate, and the borate salts as described in U.S. Pat. Nos. 6,232,038 and 6,218,076; haloalkyl substituted s-triazines such as 2,4-bis(trichloromethyl)-6-(p-methoxy-styryl)-s-triazine, 2,4-bis(trichloromethyl)-6-(4-methoxy-naphth-1-yl)-s-triazine, 2,4-bis(trichloromethyl)-6-piperonyl-s-triazine, and 2,4-bis(trichloromethyl)-6-[(4-ethoxyethylenoxy)-phen-1-yl]-s-triazine, and the s-triazines as described in U.S. Pat. Nos. 5,955,238, 6,037,098, 6,010,824, and 5,629,354; titanocene compounds such as bis(η⁹-2,4-cyclopentadien-1-yl)bis[2,6-difluoro-3-(1H-pyrrol-1-yl)phenyl)titanium; hexaarylbiimidazole compounds such as 2,2′-bis(2-chlorophenyl)-4,4′,5,5′-tetraphenyl-1,1′-biimidazole, 2,2-bis(2-ethoxyphenyl)-4,4′,5,5′-tetraphenyl-1,1′-biimidazole, 2-(1-naphthyl)-4,5-diphenyl-1,2′-biimidazole; and derivatives of acetophenone such as 2,2-dimethoxy-2-phenylacetophenone, and 2-methyl-1-[4-(methylthio)phenyl]-2-morpholino propan-1-one. Triarylsulfonium salts, diaryliodonium salts, and triarylalkylborate salts are preferred initiators for infrared laser sensitive plate. Titanocene compounds and hexaarylbiimidazole compounds are preferred initiators for visible or ultraviolet laser sensitive plate, and hexaarylbiimidazole compounds are more preferred. The initiator is added in the photosensitive layer preferably at 0.1 to 40% by weight of the photosensitive layer more preferably 1 to 30%, and most preferably 5 to 20%.

Infrared sensitizing dyes useful in the infrared sensitive photosensitive layer (also called thermosensitive layer) of this invention include any infrared absorbing dye effectively absorbing an infrared radiation having a wavelength of 750 to 1200 nm. It is preferable that the dye has an absorption maximum between the wavelengths of 780 and 1100 nm. Various infrared absorbing dyes are described in U.S. Pat. Nos. 5,858,604, 5,922,502, 6,022,668, 5,705,309, 6,017,677, and 5,677,106, and in the book entitled “Infrared Absorbing Dyes” edited by Masaru Matsuoka, Plenum Press, New York (1990), and can be used in the thermosensitive layer of this invention. Examples of useful infrared absorbing dyes include squarylium, croconate, cyanine (including polymethine), phthalocyanine (including naphthalocyanine), merocyanine, chalcogenopyryloarylidene, oxyindolizine, quinoid, indolizine, pyrylium and metal dithiolene dyes. Cyanine and phthalocyanine dyes are preferred infrared absorbing dyes. The infrared laser sensitizing dye is added in the photosensitive layer preferably at 0.1 to 20% by weight of the photosensitive layer, more preferably 0.5 to 10%, and most preferably 1 to 5%.

Visible or ultraviolet sensitizing dyes useful in the visible or ultraviolet sensitive photosensitive layer of this invention include any dyes having a wavelength maximum of from 200 to 600 nm. Suitable visible or ultraviolet sensitive dyes include, for example, cyanine dyes; rhodamine compounds such as rhodamine 6G perchloride; chromanone compounds such as 4-diethylaminobenzilidene chromanone; dialkylaminobenzene compounds such as ethyl 4-dimethylaminobenzoate and dialkylaminobenzene; dialkylaminobenzophenone compounds such as 4,4′-bis(dimethylamino)benzophenone, 4,4′-bis(diethylamino)benzophenone, 2-(p-dimethylaminophenyl)benzooxazole, 2-(p-diethylaminophenyl)benzooxazole, 2-(p-dimethylaminophenyl)benzo[4,5]benzooxazole, 2-(p-dimethylaminophenyl)benzo[6,7]benzooxazole, 2,5-bis(p-diethylaminophenyl)1,3,4-oxazole, 2-(p-dimethylaminophenyl)benzothiazole, 2-(p-diethylaminophenyl)benzothiazole, 2-(p-dimethylaminophenyl)benzimidazole, 2-(p-diethylaminophenyl)benzimidazole, 2,5-bis(p-diethylaminophenyl)1,3,4-thiadiazole, (p-dimethylaminophenyl)pyridine, (p-diethylaminophenyl)pyridine, 2-(p-dimethylaminophenyl)quinoline, 2-(p-diethylaminophenyl)quinoline, 2-(p-dimethylaminophenyl)pyrimidine or 2-(p-diethylaminophenyl)pyrimidine; unsaturated cyclopentanone compounds such as 2,5-bis{[4-(diethylamino)phenyl]methylene}-(2E,5E)-(9Cl)-cyclopentanone and bis(methylindolenyl)cyclopentanone; coumarin compounds such as 3-benzoyl-7-methoxy coumarin and 7-methoxy coumarin; and thioxanthene compounds such as 2-isopropylthioxanthenone. Dialkylaminobenzene compounds and bis(dialkylamino)benzophenone compounds are particularly suitable for ultraviolet laser sensitive plate. Bis(dialkylamino)benzophenone compounds are particularly suitable for violet laser sensitive plate. The sensitizing dyes as described in U.S. Pat. Nos. 5,422,204 and 6,689,537, and U.S. Pat. App. Pub. No. 2003/0186165 can be used for the photosensitive layer of this invention. The visible or ultraviolet laser sensitizing dye is added in the photosensitive layer preferably at 0.1 to 20% by weight of the photosensitive layer, more preferably 0.5 to 15%, and most preferably 1 to 10%.

The free radical polymerizable photosensitive composition of the present invention preferably contains one or more hydrogen donors as a polymerization accelerator. Examples of the hydrogen donors include compounds having a mercapto group (also called mercapto compounds) such as 2-mercaptobenzothiazole, 2-mercaptobenzimidazole, 2-mercaptobenzoxazole and 3-mercapto-1,2,4-triazole; and N-aryl-α-amino acids, their salts and esters such as N-phenylglycine, salts of N-phenylglycine, and alkyl esters of N-phenylglycine such as N-phenylglycine ethyl ester and N-phenylglycine benzyl ester. Preferred hydrogen donors are 2-mercaptobenzothiazole, 2-mercaptobenzimidazole, 2-mercaptobenzoxazole, 3-mercapto-1,2,4-triazole, N-phenylglycine, N-phenylglycine ethyl ester, and N-phenylglycine benzyl ester. Combination of at least one mercapto compound and at least one N-aryl-α-amino acid or its ester or salt can be advantageously used in the photosensitive layer to increase the photospeed. The hydrogen donor is added in the photosensitive layer preferably at 0.01 to 15% by weight of the photosensitive layer, more preferably 0.1 to 10%, and most preferably 0.5 to 5%.

Various surfactants may be added into the photosensitive layer to, for example, improve the coatability or developability. Both polymeric and small molecule surfactants can be used. However, it is preferred that the surfactant has low or no volatility so that it will not evaporate from the photosensitive layer of the plate during storage and handling. Nonionic surfactants are preferred. Preferred nonionic surfactants are polymers and oligomers containing one or more polyether (such as polyethylene glycol, polypropylene glycol, and copolymer of ethylene glycol and propylene glycol) segments. Examples of preferred nonionic surfactants are block copolymers of propylene glycol and ethylene glycol (also called block copolymer of propylene oxide and ethylene oxide); ethoxylated or propoxylated acrylate oligomers; and polyethoxylated alkylphenols and polyethoxylated fatty alcohols. The nonionic surfactant is preferably added at from 0.1 to 10% by weight of the photosensitive layer, and more preferably from 0.5 to 5%.

A hydrophilic or oleophilic micro particles may be added into the photosensitive layer to enhance, for example, the developability and non-tackiness of the plate. Suitable micro panicles include polymer particles, talc, titanium dioxide, barium sulfate, silicone oxide and aluminum micro particles, with an average particle size of less than 10 microns, preferably less than 5 microns, more preferably less than 2 microns and most preferably less than 1 microns. A suitable particular dispersion is described in U.S. Pat. No. 6,071,675, the entire disclosure of which is hereby incorporated by reference.

For plates with rough and/or porous surface capable of mechanical interlocking with a coating deposited thereon, a thin water-soluble interlayer can be deposited between the substrate and the photosensitive layer. Here the substrate surface is rough and/or porous enough and the interlayer is thin enough to allow bonding between the photosensitive layer and the substrate through mechanical interlocking. Such a plate configuration is described in U.S. Pat. No. 6,014,929, the entire disclosure of which is hereby incorporated by reference. Preferred releasable interlayer comprises a water-soluble polymer. Polyvinyl alcohol (including various water-soluble derivatives of polyvinyl alcohol) is a preferred water-soluble polymer. Usually pure water-soluble polymer is coated. However, one or more surfactants and/or other additives (such as bactericide, defoamer, and water soluble dye) may be added. The releasable interlayer preferably has an average coverage of 1 to 200 mg/m², more preferably 2 to 100 mg/m², and most preferably 4 to 40 mg/m². The substrate preferably has an average surface roughness Ra of 0.2 to 2.0 microns, and more preferably 0.4 to 1.0 microns.

The photosensitive layer may be conformally coated onto a roughened substrate (for example, with Ra of larger than 0.4 microns) at thin coverage (for example, of less than 1.2 g/m²) so that the plate can have microscopic peaks and valleys on the photosensitive layer coated surface and exhibit low tackiness and good block resistance, as described in U.S. Pat. No. 6,242,156, the entire disclosure of which is hereby incorporated by reference.

A water soluble or dispersible overcoat can be coated on the photosensitive layer to, for example improve the photospeed surface durability, and/or on-press developability of the plate. The overcoat preferably comprises a water-soluble polymer such as polyvinyl alcohol (including various water-soluble derivatives of polyvinyl alcohol). Combination of two or more water-soluble polymers (such as a combination of polyvinyl alcohol and polyvinylpyrrolidone) may also be used. Polyvinyl alcohol is a preferred water-soluble polymer. Various additives, such as surfactant, wetting agent, defoamer, leveling agent and dispersing agent, can be added into the overcoat formulation to facilitate, for example, the coating or development process. Examples of surfactants useful in the overcoat of this invention include polyethylene glycol, polypropylene glycol, and copolymer of ethylene glycol and propylene glycol, polysiloxane surfactants, perfluorocarbon surfactants, alkylphenyl ethylene oxide condensate sodium dioctylsulfosuccinate, sodium dodecylbenzenesulfonate, and ammonium laurylsulfate. Various organic or inorganic micro particles (such as talc and polymer particles) can be added into the overcoat to, for example, reduce the tackiness or moisture sensitivity of the plate. The overcoat preferably has a coverage of from 0.001 to 4.0 g/m², more preferably from 0.01 to 2.0 g/m², and most preferably from 0.1 to 1.0 g/m².

A preferred thermosensitive lithographic printing plate of this invention comprises on a substrate a thermosensitive layer comprising a polymeric binder, a polymerizable ethylenically unsaturated monomer having at least one terminal ethylenic group, a free-radical initiators and an infrared absorbing dye. Other additives such as surfactant, dye or pigment, exposure-indicating dye (such as leuco crystal violet, leucomalachite green, azobenzene, 4-phenylazodiphenylamine, and methylene blue dyes), and free-radical stabilizer (such as methoxyhydroquinone) may be added. The weight ratio of all the monomers to all the polymeric binders is preferably at least 1.0, more preferably at least 1.5, and most preferably at least 2.0.

Another preferred thermosensitive lithographic plate of this invention comprises on a substrate a thermosensitive layer comprising a polymeric binder, a urethane (meth)acrylate monomer having at least 4 (meth)acrylate groups, a free-radical initiator, and an infrared absorbing dye.

Yet another preferred thermosensitive lithographic plate of this invention comprises on a substrate a thermosensitive layer comprising a polymeric binder having polymer backbone with recurring units having pendant poly(alkylene glycol) side chains, a (meth)acrylate monomer having at least one (meth)acrylate group, a free-radical initiator, and an infrared absorbing dye.

Further another preferred thermosensitive lithographic plate of this invention comprises on a substrate a thermosensitive layer comprising a polymeric binder and an infrared absorbing dye or pigment (preferably infrared absorbing dye); said thermosensitive layer is developable with ink and/or fountain solution and capable of hardening through crosslinking of the polymeric binder upon exposure to an infrared laser. A nonionic surfactant and/or a water-soluble polymer are preferably added in the thermosensitive layer. Other additives such as other surfactant, dye or pigment, and exposure indicating dye can also be added.

Yet further another preferred thermosensitive lithographic plate of this invention comprises on a substrate a thermosensitive layer comprising polymeric particles and an infrared absorbing dye or pigment (preferably infrared absorbing dye); said thermosensitive layer is developable with ink and/or fountain solution and capable of hardening through coalescence of the polymer particles upon exposure to an infrared laser. A nonionic surfactant and/or a water-soluble polymer are preferably added in the thermosensitive layer. Other additives such as other surfactant, dye or pigment, and exposure indicating dye can also be added.

A preferred visible light sensitive lithographic printing plate of this invention comprises on a substrate a photosensitive layer comprising a polymeric binder, a polymerizable ethylenically unsaturated monomer, a free-radical initiator, and a visible light sensitizing dye. A hydrogen donor is preferably added to increase the photospeed. Other additives such as surfactant, dye or pigment, exposure-indicating dye, and free-radical stabilizer may be added. The weight ratio of all the monomers to all the polymeric binders is preferably at least 1.0, more preferably at least 1.5, and most preferably at least 2.0.

A preferred violet or ultraviolet light sensitive lithographic printing plate of this invention comprises on a substrate a photosensitive layer comprising a polymeric binder, a polymerizable ethylenically unsaturated monomer having at least one terminal ethylenic group, a free-radical initiator, and a violet or ultraviolet sensitizing dye. A hydrogen donor is preferably added to increase the photospeed. Other additives such as surfactant, dye or pigment, exposure-indicating dye, and free-radical stabilizer may be added. The weight ratio of all the monomers to all the polymeric binders is preferably at least 1.0, more preferably at least 1.5, and most preferably at least 2.0.

Another preferred violet or ultraviolet light sensitive lithographic plate of this invention comprises on a substrate a photosensitive layer comprising a polymeric binder a monomer having at least 3 (meth)acrylate group, a hexaarylbiimidazole or titanocene compound, a dialkylaminobenzophenone compound, and a hydrogen donor. The weight ratio of all the monomers to all the polymeric binders is preferably at least 1.0, more preferably from 1.5 to 6.0, and most preferably from 2.0 to 5.0. A hexaarylbiimidazole compound is preferred among hexaarylbiimidazole and titanocene compounds. A preferred dialkylaminobenzophenone compound is a 4,4′-bis(dialkylamino)benzophenone compound.

Yet another preferred violet or ultraviolet light sensitive lithographic plate of this invention comprises on a substrate a photosensitive layer comprising a polymeric binder, a urethane monomer having at least 4 (meth)acrylate group, a hexaarylbiimidazole or titanocene compound, a dialkylaminobenzophenone compound, and a hydrogen donor. The weight ratio of all the monomers to all the polymeric binders is preferably at least 0.5, more preferably from 1.0 to 6.0, and most preferably from 2.0 to 5.0. A hexaarylbiimidazole compound is preferred among hexaarylbiimidazole and titanocene compounds. A preferred dialkylaminobenzophenone compound is a 4,4′-bis(dialkylamino)benzophenone compound. A non-urethane (meth)acrylate monomer can be added.

Further another preferred violet or ultraviolet light sensitive lithographic plate of this invention comprises on a substrate a photosensitive layer comprising a polymeric binder, a urethane monomer having at least 4 (meth)acrylate group, a non-urethane monomer having at least 4 (meth)acrylate groups, a hexaarylbiimidazole or titanocene compound, a dialkylaminobenzophenone compound, and a hydrogen donor. The weight ratio of all the urethane (meth)acrylate monomera to all the non-urethane (meth)acrylate monomers is preferably from 0.10 to 10.0, more preferably from 0.20 to 5.0, and most preferably from 0.30 to 3.0. The weight ratio of all the monomers to all the polymeric binders is preferably at least 0.5, more preferably from 1.0 to 6.0, even more preferably from 1.5 to 5.0, and most preferably from 2.0 to 4.0. A hexaarylbiimidazole compound is preferred among hexaarylbiimidazole and titanocene compounds. A preferred dialkylaminobenzophenone compound is a 4,4′-bis(dialkylamino)benzophenone compound.

Yet further another preferred violet or ultraviolet light sensitive lithographic plate of this invention comprises on a substrate a photosensitive layer comprising a polymeric binder having polymer backbone with recurring units having pendant poly(alkylene glycol) side chains, a (meth)acrylate monomer having at least one (meth)acrylate group, a free-radical initiator, and a violet or ultraviolet sensitizing dye. A hydrogen donor is preferably added. Other additives such as surfactant, dye or pigment, exposure-indicating dye, and free-radical stabilizer may be added.

The on-press developable lithographic plates and on-press developable photosensitive compositions as described in U.S. Pat. Nos. 6,482,571, 6,576,401, 5,548,222, 6,541,183, and 7,213,516, and U.S. patent application Ser. Nos. 10/720,882, 11/075,663, 11/175,518, 11/336,132, 11/356,911, 11/504,565, 11/595,468, 11/645,376, and 11/826,576, the entire disclosures of which are hereby incorporated by reference, can be used for the instant invention.

Infrared lasers useful for the imagewise exposure of the thermosensitive plates of this invention include laser sources emitting in the near infrared region, i.e., emitting in the wavelength range of from 750 to 1200 mm, and preferably from 800 to 1100 nm. Particularly preferred infrared laser sources are laser diodes emitting around 830 nm or a Nd/YAG laser emitting around 1060 nm. The plate is exposed at a laser dosage that is sufficient to cause hardening or solubilization in the exposed areas but not high enough to cause substantial thermal ablation. The exposure dosage is preferably from 1 to 500 mJ/cm², more preferably from 10 to 300 mJ/cm², and most preferably from 50 to 200 mJ/cm², depending on the sensitivity of the thermosensitive layer.

Visible lasers useful for the imagewise exposure of the visible light sensitive plates of this invention include any laser emitting in the wavelength range of from 390 to 600 nm. Examples of suitable visible lasers include frequency-doubled Nd/YAG laser (about 532 nm), argon ion laser (about 488 nm), violet diode laser (about 405 nm), and visible LEDs. Violet laser diode is especially useful because of its small size and relatively lower cost. The exposure dosage is preferably from 0.001 to 2 mJ/cm² (1 to 2000 μJ/cm²) more preferably from 0.005 to 0.4 mJ/cm² (5 to 400 μJ/cm²), and most preferably from 0.02 to 0.20 mJ/cm² (20 to 200 μJ/cm²), depending on the sensitivity of the photosensitive layer.

Ultraviolet lasers useful for the imagewise exposure of the ultraviolet light sensitive plates of this invention include any laser having a wavelength of from 200 to 390 nm. Examples of ultraviolet lasers include ultraviolet diode lasers or LEDs having a wavelength of from 350 to 390 nm. Laser diodes are preferred ultraviolet lasers. The exposure dosage is preferably from 0.001 to 2 mJ/cm² (1 to 2000 μJ/cm²), more preferably from 0.005 to 0.4 mJ/cm² (5 to 400 μJ/cm²), and most preferably from 0.02 to 0.20 mJ/cm² (20 to 200 μJ/cm²), depending on the sensitivity of the photosensitive layer.

Among the visible and ultraviolet lasers, violet or ultraviolet laser (with a wavelength selected from 200 to 430 nm) is particularly useful.

Laser imaging devices are currently widely available commercially. Any device can be used which provides imagewise laser exposure according to digital imaging information. Commonly used imaging devices include flatbed imager, internal drum imager, and external drum imager, all of which can be used for the imagewise laser exposure in this invention.

The plate is preferably exposed on an exposure device, treated with a treating solution on a treating device, and then mounted on press to develop with ink and/or fountain solution and then print out regular printed sheets. Preferably, the plate is under a safe light or in substantial darkness during imagewise exposure and treatment. The ink and/or fountain solution solubilized or dispersed photosensitive layer (and overcoat if any) can be mixed into the ink and/or the fountain solution on the rollers, and/or can be transferred to the blanket and then the receiving medium (such as paper). The fountain solution roller is engaged (to the plate cylinder as for conventional inking system or to the ink roller as for integrated inking system) for preferably 0 to 100 rotations, more preferably 1 to 50 rotations and most preferably 5 to 20 rotations (of the plate cylinder), and the ink roller is then engaged to the plate cylinder for preferably 0 to 100 rotations, more preferably 1 to 50 rotations and most preferably 5 to 20 rotations before engaging the plate cylinder and feeding the receiving medium. Good quality prints should be obtained preferably under 40 initial impressions, more preferably under 20 impressions, and most preferably under 5 impressions.

For conventional wet press, usually fountain solution is applied (to contact the plate) first, followed by contacting with ink roller. For press with integrated inking/dampening system, the ink and fountain solution are emulsified by various press rollers before being transferred to the plate as emulsion of ink and fountain solution. However, in this invention, the ink and fountain solution may be applied at any combination or sequence, as needed for the plate. There is no particular limitation.

The ink used in this application can be any ink suitable for lithographic printing. Most commonly used lithographic inks include “oil based ink,” which crosslinks upon exposure to the oxygen in the air and “rubber based ink” which does not crosslink upon exposure to the air. Specialty inks include, for example, radiation-curable ink and thermally curable ink. An ink is an oleophilic, liquid or viscous material which generally comprises a pigment dispersed in a vehicle, such as vegetable oils, animal oils, mineral oils, and synthetic resins. Various additives, such as plasticizer, surfactant, drier, drying retarder, crosslinker, and solvent may be added to achieve certain desired performance. The compositions of typical lithographic inks are described in “The Manual of Lithography” by Vicary, Charles Scribner's Sons, New York, and Chapter 8 of “The Radiation Curing Science and Technology” by Pappas, Plenum Press, New York, 1992.

The fountain solution used in this application can be any fountain solution used in lithographic printing. Fountain solution is used in the wet lithographic printing press to dampen the hydrophilic areas (non-image areas), repelling ink (which is hydrophobic) from these areas. Fountain solution contains mainly water, generally with addition of certain additives such as gum arabic and surfactant. Small amount of alcohol such as isopropanol can also be added in the fountain solution. Water is the simplest type of fountain solution. Fountain solution is usually neutral to mildly acidic. However, for certain plates, mildly basic fountain solution may be used. The type of fountain solution used depends on the type of the plate substrate as well as the photosensitive layer. Various fountain solution compositions are described in U.S. Pat. Nos. 4,030,417 and 4,764,213.

This invention is further illustrated by the following non-limiting examples of its practice.

### EXAMPLES 1-6

An electrochemically grained, anodized, and silicated aluminum sheet was coated with the photosensitive layer formulation PS-1 with a #8 Meyer rod, followed by drying in an oven at 100° C. for 2 min. All the coatings were performed under a yellow light.

PS-1

| Component | Weight (g) |
|---|---|
| Neocryl B-728 (Polymer from Zeneca) | 2.48 |
| Ebecryl 220 (Monomer from UCB Chemicals) | 1.64 |
| Sartomer SR-399 (Monomer from Sartomer Company) | 4.29 |
| Pluronic L43 (Surfactant from BASF) | 0.51 |
| Leucomalachite green (Exposure indicator) | 0.53 |
| 2,6-Di-tert-butyl-4-methylphenol (Antioxidant) | 0.01 |
| Irganox 1035 (Antioxidant from Ciba-Geigy) | 0.01 |
| 4-piperonyl-2,6-bis(trichloromethyl)-s-triazine (Initiator) | 0.52 |
| 2-Butanone | 90.00 |

The plate was open to an office white fluorescence light for 60 minutes to turn on the green color from the leuco malachite green. The office-light exposed plate has bright blue color all over the photosensitive layer of the plate, with the coating remaining non-hardened (still developable with ink and fountain solution). This green-colored plate was imagewise exposed through a negative mask to an ultraviolet light with an emission maximum of about 365 nm under vacuum for 2 minutes, using an ultraviolet light exposure device with a 1000 watts light bulb (INSTANT 2 VACUUM PRINTER 24×28, from Berkey Technical Co., New York). The imagewise exposed areas showed greener color. This imagewise exposed plate was cut into 6 sheets for further evaluation.

The first sheet of the imagewise exposed plate was dipped in a 10% citric acid aqueous solution for 20 seconds and then dried naturally at room temperature. The color in the non-imagewise exposed areas faded significantly while the color in the imagewise exposed areas showed essentially no change, giving sharper image contrast on the photosensitive layer. The sharp image contrast remained substantially unchanged under white office light. The treated plate was then mounted on the plate cylinder of an AB Dick 360 lithographic press to test for on-press development and printing. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper for 200 impressions (no further test was conducted). The plate rolled up to clean background, good inking, and 1-98% resolution under 10 impressions (of printed sheets), with no wearing observed at 200 impressions.

The second sheet of the imagewise exposed plate was tested the same as with the first sheet except that the plate was treated with a 5% acetic acid aqueous solution instead of citric acid solution. After dipping the plate in the acetic acid solution for 20 seconds, the color in the non-hardened areas faded while the color in the hardened areas remained unchanged. The plate tested on press rolled up to clean background, good inking, and 1-98% resolution under 10 impressions, with no wearing observed at 200 impressions.

The third sheet of the imagewise exposed plate was tested the same as with the first sheet except that the plate was treated with a household bleach Clorox (containing 5-8% sodium hypochlorite and 0.5-1% sodium hydroxide in water, from Clorox Company) instead of citric acid solution. After dipping the plate in Clorox for 60 seconds, the color in the non-hardened areas faded while the color in the hardened areas remained substantially unchanged. The plate tested on press gave roll up to clean background, good inking, and 1-98% resolution under 10 impressions, with no wearing observed at 200 impressions.

The fourth sheet of the imagewise exposed plate was tested the same as with the first sheet except that the plate was treated with a 0.2% by weight sodium hydroxide aqueous solution instead of citric acid solution. After dipping the plate in the sodium hydroxide solution for 20 seconds, the color in the non-hardened areas faded while the color in the hardened areas remained substantially unchanged. The plate tested on press rolled up to clean background, good inking, and 1-98% resolution under 10 impressions, with no wearing observed at 200 impressions.

The fifth sheet of the imagewise exposed plate was tested the same as with the first sheet except that the plate was treated with a 0.4% by weight potassium hydroxide aqueous solution instead of citric acid solution. After dipping the plate in the potassium hydroxide solution for 20 seconds, the color in the non-hardened areas faded while the color in the hardened areas remained substantially unchanged. The plate tested on press rolled up to clean background, good inking, and 1-98% resolution under 10 impressions, with no wearing observed at 200 impressions.

The sixth sheet of the imagewise exposed plate was tested the same as with the first sheet except that the plate was treated with a 4% by weight sodium silicate aqueous solution instead of citric acid solution. After dipping the plate in the sodium silicate solution for 60 seconds, the color in the non-hardened areas faded while the color in the hardened areas remained substantially unchanged. The plate tested on press rolled up to clean background, good inking, and 1-98% resolution under 10 impressions, with no wearing observed at 200 impressions.

### EXAMPLE 7

An electrochemically grained, anodized, and phosphate-fluoride treated aluminum sheet was first coated with a 0.1% aqueous solution of polyvinyl alcohol (Airvol 540, from Air Products) with a #6 Meyer rod, followed by drying in an oven at 100° C. for 2 min. The polyvinyl alcohol coated substrate was further coated with the photosensitive layer formulation PS-2 with a #6 Meyer rod, followed by drying in an oven at 100° C. for 2 min.

PS-2

| Component | Weight (g) |
|---|---|
| Carboset 527 (Alkaline soluble polymeric binder with acid | 1.93 |
| number of 80, from B. F. Goodrich) | |
| Ebecryl 220 (Blend of a hexafunctional aromatic acrylate | 5.43 |
| monomer and a tetrafunctional non-urethane aliphatic | |
| Renol Blue B2G-HW (Blue pigment dispersed in polyvinyl- | 0.42 |
| butyral from Clariant) | |
| Pluronic L43 (Nonionic surfactant from BASF) | 0.53 |
| 2,2-Bis(2-chlorophenyl)-4,4′,5,5′-tetraphenyl-1,1′-biimidazole | 1.09 |
| 4,4′-Bis(diethylamino)benzophenone | 0.49 |
| 2-Mercaptobenzoxazole | 0.12 |
| Acetone | 27.00 |
| 2-Methoxypropanol | 63.00 |

The photosensitive layer coated plate was further coated with a water-soluble overcoat OC-1 using a #6 Meyer rod, followed by hot air blow drying and baking in an oven at 100° C. for 2 min. All the coatings were performed under a red light and the plate was then stored in a light tight box.

OC-1

| | Weight |
|---|---|
| Component | ratios |
| Airvol 205 (Polyvinyl alcohol from Air Products) | 0.2 |
| Dioctyl sulfosuccinate sodium salt (surfactant) | 0.01 |
| Water | 99.8 |

The plate was exposed with a violet plate imager equipped with a 60 mw violet laser diode emitting at about 405 nm (MAKO-8 from ECRM) for a dosage of about 90 μJ/cm². The plate was imaged in an orange light room (with Fuji Yellow FV30 lights from Encapsulite), and was kept in a light tight box before and after imaging.

The laser exposed plate was treated with a solution containing 10% by weight citric acid in a blend of acetone and water at a weight ratio of 1:1 by dipping in the solution for 20 seconds, followed by hot air blow drying with a hair drier to remove the water and solvent. The treated plate was evaluated at white office light. The exposed areas showed essentially unchanged original blue color, while non-exposed areas showed dull, less blue color.

The treated plate was further mounted on the plate cylinder of an AB Dick 360 lithographic press for on-press development and printing tests, under white room light. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper for 200 impressions. The plate rolled up to clean background, good inking, and 2-98% resolution under 20 impressions, with no wearing observed at 200 impressions.

### EXAMPLES 8-11

A plate prepared and imagewise exposed the same as in EXAMPLE 7 was treated with a solution containing 10% by weight citric acid aqueous solution by dipping in the solution for 30 seconds, followed by air drying to dry off the overflowing liquid. Half of the treated plate (with the other half covered with a red masking sheet) was exposed to a 1000 walls ultraviolet light for 1 minute on an ultraviolet light exposure device (INSTANT 2 VACUUM PRINTER 24×28, from Berkey Technical Co., New York).

The treated plate was further mounted on the plate cylinder of an AB Dick 360 lithographic press for on-press development and printing tests, under white room light. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper for 200 impressions. Both the ultraviolet exposed half and the ultraviolet non-exposed half of the plate rolled up to clean background and good inking under 20 impressions (of printed sheets). The plate exposed with ultraviolet light showed 1-98% resolution, compared to 2-98% for the plate not exposed with ultraviolet light.

Another plate prepared and imagewise exposed the same as in EXAMPLE 7 was directly exposed to the same 1000 watts ultraviolet light for 1 minute, without any treatment. The plate was tested on press the same as above. Both the imagewise non-exposed areas and imagewise exposed areas took ink, indicating hardening of the whole plate.

Yet another plate prepared and imagewise exposed the same as in EXAMPLE 7 was exposed to the office white fluorescence light for 10 minutes, without any treatment. The plate was tested on press the same as above. Both the imagewise non-exposed areas and imagewise exposed areas took ink, indicating hardening of the whole plate.

### EXAMPLES 12-14

An electrochemically grained, anodized, and polyvinylphosphonic acid treated aluminum sheet was first coated with a 0.1% aqueous solution of polyvinyl alcohol (Airvol 540, from Air Products) with a #6 Meyer rod, followed by drying in an oven at 100° C. for 2 min. The polyvinyl alcohol coated substrate was further coated with the photosensitive layer formulation PS-3 with a #8 Meyer rod, followed by drying in an oven at 90° C. for 2 min.

PS-3

| | Weight |
|---|---|
| Component | ratios |
| Neocryl B-728 (Polymer from Zeneca) | 2.75 |
| DPHA (Acrylic monomer from UCB Chemicals) | 6.56 |
| Pluronic L43 (Nonionic surfactant from BASF) | 0.56 |
| 2,2-Bis(2-chlorophenyl)-4,4′,5,5′-tetraphenyl-1,1′-biimidazole | 1.21 |
| 4,4′-Bis(diethylamino)benzophenone | 0.77 |
| 2-Mercaptobenzoxazole | 0.15 |
| 2-Butanone | 88.00 |

The photosensitive layer coated plate was further coated with a water-soluble overcoat OC-2 using a #6 Meyer rod, followed by drying in an oven at 100° C. for 2 min. All the coatings were performed under a red light and the plate was then stored in a light tight box.

OC-2

| Component | Weight (g) |
|---|---|
| Airvol 203 (polyvinyl alcohol from Air Products) | 4.84 |
| Silwet 7604 (Surfactant from Union Carbide) | 0.02 |
| Triton X-100 (Surfactant from www.chemistrystore.com) | 0.14 |
| Water | 95.00 |

The plate was exposed with a violet plate imager equipped with a 60 mw violet laser diode emitting at about 405 nm (MAKO-8 from ECRM) for a dosage of about 90 μJ/cm². The plate was imaged in an orange light room (with Fuji Yellow FV30 lights from Encapsulite), and was kept in a light tight box before and after imaging.

The laser exposed plate was cut into 3 pieces under red light. The first piece was treated with a 5% citric acid aqueous solution by dipping in the solution for 10 seconds. The second piece was rinsed with water by dipping in water for 5 seconds to remove the overcoat. The third piece was not treated. The treatments were performed under red light.

Each of the treated plates was tested on a wet lithographic press (AB Dick 360) under office (while) fluorescent light. The plate was directly mounted on the plate cylinder of the press. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper for 200 impressions. The printed sheets were evaluated for on-press developability of the plate, with the results summarized in Table 1.

TABLE 1

| | Background | Background | Inking |
|---|---|---|---|
| | at 20 | at 200 | in imaging |
| Treatment of the plate | impressions | impressions | areas |
| Dip in a 5% citric | Clean | Clean | Good |
| acid aqueous solution | | | |
| Rinse with water | Toning | Toning | Good |
| No treatment | Inked | Inked | Good |

### EXAMPLES 15-20

An electrochemically grained, anodized and polyvinylphosphonic acid treated aluminum substrate was coated with a thermosensitive layer formulation PS-4 with a #6 Meyer rod, followed by drying in an oven at 100° C. for 2 min.

PS-4

| Component | Weight (g) |
|---|---|
| Neocryl B-728 (Polymer from Zeneca) | 2.50 |
| Ebecryl 220 (Acrylate monomer from UCB Chemicals) | 5.99 |
| Pluronic L43 (Nonionic surfactant from BASF) | 0.40 |
| (4-(2-Hydroxytetradecyl-oxy)phenyl)phenyliodonium | 1.00 |
| hexafluorophosphate | |
| PINA KF-1151 (Infrared absorbing polymethine dye | 0.10 |
| from Allied Signal) | |
| 2-Butanone | 90.00 |

The thermosensitive layer coated plate was further coated with a water-soluble overcoat OC-2 using a #6 Meyer rod, followed by hot air blow drying and baking in an oven at 100° C. for 2 min.

The coated plate was exposed with an infrared laser imager equipped with laser diodes emitting at about 830 nm (Trendsetter from Creo) at a dosage of about 200 mJ/cm². The exposed areas of the plate showed brown color, while the non-exposed areas remain light green. The exposed plate was cut into 6 pieces for further tests.

The first piece was dipped in a 10% by weight citric acid aqueous solution for 20 seconds. The second piece was dipped in a 10% by weight sodium chloride aqueous solution for 20 seconds. The third piece was dipped in a 0.2% by weight sodium hydroxide aqueous solution for 20 seconds. The fourth piece was dipped in a 10% by weight sodium xylenesulfonate aqueous solution for 20 seconds. The fifth piece was rinsed with water. All the above pieces of plate were dried by hot air blow to remove any excess water. The treatments were performed under yellow light. The sixth piece was not treated. All the above plate pieces were then exposed to an office white fluorescent light (total of 80 watts at about 2 meters) for 2 hours. The appearances of the plate pieces were listed in Table 1.

Each of the treated plates was tested on a wet lithographic press AB Dick 360 (under office white fluorescent light). The plate was directly mounted on the plate cylinder of the press. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper for 200 impressions. The printed sheets were evaluated for on-press developability of the plate, with the results summarized in Table 2.

TABLE 2

| | Appearance after laser | | Performance on AB Dick 360 | | |
|---|---|---|---|---|---|
| | exposure and treatment | | lithographic press | | |
| | Non- | Laser | Background | Background | Inking in |
| Aqueous solution for | exposed | exposed | at 20 | at 200 | imaging |
| treating plate | areas | areas | impressions | impressions | areas |
| 10% Citric acid | Light green | Brown | Clean | Clean | Good |
| 10% Sodium chloride | Light green | Brown | Clean | Clean | Good |
| 0.2% Sodium hydroxide | Light green | Light brown | Clean | Clean | Good |
| 10% Sodium | Light green | Light brown | Clean | Clean | Good |
| xylenesulfonate | | | | | |
| Rinse with water | Light green | Brown | Toning | Toning | Good |
| No treatment | Light green | Brown | Inked | Inked | Good |

### EXAMPLE 21

A plate was prepared and imagewise exposed the same as in EXAMPLES 15-20, and then dipped in a 0.2% by weight sodium hydroxide aqueous solution for 20 seconds followed by hot air blow to dry off excess water. The imagewise non-exposed areas was light green and the imagewise exposed areas was light brown. The treated plate was further exposed with a 1000 watts ultraviolet light for 1 minute on an ultraviolet light exposure device (INSTANT 2 VACUUM PRINTER 24×28, from Berkey Technical Co., New York). The imagewise non-exposed areas became essentially colorless and the imagewise exposed became dark brown.

The plate was further tested on a wet lithographic press AB Dick 360 (under office white fluorescent light). The plate was directly mounted on the plate cylinder of the press. After starting the press, the fountain roller was engaged for 20 rotations, the ink roller (carrying emulsion of ink and fountain solution) was applied to the plate cylinder for 20 rotations, and the plate cylinder was then engaged with the blanket cylinder and printed with paper for 200 impressions. The plate rolled up to clean background, good inking and 2-98% resolution under 20 impressions, with no wearing observed at 200 impressions.

I claim:

1. A lithographic printing plate treating device comprising:
(a) a structure for providing a treating solution;
(b) an exposed lithographic plate comprising on a substrate a photosensitive layer having hardened or solubilized exposed areas and non-hardened or non-solubilized non-exposed areas, the non-hardened (for negative plate) or solubilized (for positive plate) areas of said photosensitive layer being removable on press with ink and/or fountain solution; and
(c) a transfer means for transporting said exposed plate through said structure to contact said treating solution with at least the photosensitive layer coated side of said plate without developing said plate.

2. The device of claim 1 wherein said exposed plate is prepared from a negative plate having on a substrate a photosensitive layer capable of hardening upon exposure to a laser having a wavelength selected from 200 to 1200 nm, the non-hardened areas of said photosensitive layer being removable with ink and/or fountain solution on a lithographic press.

3. The device of claim 1 wherein said exposed plate is prepared from a positive plate having on a substrate a photosensitive layer capable of solubilization upon exposure to a laser having a wavelength selected from 200 to 1200 nm, the solubilized areas of said photosensitive layer being removable with ink and/or fountain solution on a lithographic press.

4. The device of claim 1 wherein said treating solution is an aqueous solution capable of causing a chemical or physical change to the photosensitive layer or the substrate surface of said plate.

5. The device of claim 1 wherein said treating solution comprises a compound capable of chemically reacting with a compound in said photosensitive layer.

6. The device of claim 1 wherein said photosensitive layer is negative-working and is capable of hardening under a white room light, said treating solution is capable of deactivating the photo hardening capability of the photosensitive layer in the non-hardened areas, and the application of said treating solution deactivates the photosensitive layer so that the photosensitive layer in the non-hardened areas becomes incapable of hardening under said white room light.

7. The device of claim 1 wherein said photosensitive layer is positive-working and is capable of solubilization under a white room light, said treating solution is capable of deactivating the photo solubilization capability of the photosensitive layer in the non-solubilized areas, and the application of said treating solution deactivates the photosensitive layer so that the photosensitive layer in the non-solubilized areas becomes incapable of solubilization under said white room light.

8. The device of claim 1 wherein said treating solution is negative-working and is capable of causing color change of said photosensitive layer upon diffusing into it and is capable of diffusing into said photosensitive layer primarily or only in the non-hardened areas, with less or no diffusion in the hardened areas; so that the application of said treating solution causes color change primarily or only in the non-hardened areas of said photosensitive layer.

9. The device of claim 1 wherein said treating solution is positive-working and is capable of causing color change of said photosensitive layer upon diffusing into it and is capable of diffusing into said photosensitive layer primarily or only in the solubilized areas, with less or no diffusion in the non-solubilized areas; so that the application of said treating solution causes color change primarily or only in the solubilized areas of said photosensitive layer.

10. The device of claim 1 wherein said substrate is not sufficiently hydrophilic and said plate is incapable of forming completely clean background upon on-press development with ink and/or fountain solution before said treatment; said treating solution is capable of making said substrate more hydrophilic; and said treated plate is capable of forming completely clean background upon on-press development with ink and fountain solution.

11. The device of claim 1 wherein said treating solution is capable of making said photosensitive layer more soluble or dispersible in ink and/or fountain solution, and the treated plate is capable of being on-press developed at least 5 impressions faster than the untreated plate.

12. The device of claim 1 wherein said treating device does not have a developing means for developing said plate and is not connected to any developing device for developing said plate.

13. The device of claim 1 wherein said treating device further comprises a collecting tray around the exit of said treating device and said transfer means further transports said plate to the collecting tray as a treated plate without development.

14. The device of claim 1 wherein said structure is a tank containing said treating solution and said plate passes through said treating solution in said tank when passing through said structure.

15. The device of claim 1 wherein said structure contains one or more spray nozzles for spraying said treating solution to said plate when said plate passes through said structure.

16. The device of claim 1 wherein said structure contains one or more rollers for applying said treating solution to said plate when said plate passes through said structure.

17. The device of claim 1 further comprising a heating unit for heating said plate before passing said plate through said structure.

18. The device of claim 1 further comprising a drying unit for blowing hot or ambient air to the treated plate after passing said plate through said structure.

19. The device of claim 1 being shielded with covers which prevent all or substantially all of the room light or of the unsafe portion of the room light from reaching the plate when said plate is handled and treated on the treating device at least before being treated.

20. The device of claim 1 being connected to an imager for imagewise exposing said plate with a radiation before transporting the exposed plate to said device.

21. A lithographic printing plate imaging and treating assembly comprising:
(a) an imager capable of imagewise exposing a lithographic plate with a laser having a wavelength selected from 200 to 1200 nm;
(b) a lithographic plate having on a substrate a photosensitive layer capable of hardening upon exposure to said laser;
(c) a structure for providing a treating solution, said treating solution being capable of causing a chemical or physical change to said plate without developing said plate; and
(d) a transfer means for transporting said plate to said imager for imagewise exposure, then to said structure to contact with said treating solution, and further to the exit of said assembly as an exposed plate which is treated without being developed.

22. The assembly of claim 21 being shielded with covers which prevent all or substantially all of the room light or of the unsafe portion of the room light from reaching the plate on said assembly before being treated.

23. The assembly of claim 21 wherein said imager is connected to a cassette containing at least one plate and capable of automatically feeding said plate from said cassette to said imager for imagewise exposure.

24. The assembly of claim 21 wherein said laser is a violet or ultraviolet laser having a wavelength selected from 300 to 430 nm.

25. The assembly of claim 21 wherein said laser is an infrared laser having a wavelength selected from 750 to 1200 mm.

26. A method of processing a lithographic printing plate comprising in order:
(a) providing a lithographic plate comprising on a substrate a photosensitive layer capable of hardening (for negative plate) or solubilization (for positive plate) upon exposure to a radiation having a wavelength selected from 200 to 1200 nm;
(b) imagewise exposing said plate with said radiation to cause hardening or solubilization of the photosensitive layer in the exposed areas;
(c) transferring said exposed plate through a treating device to overall apply a treating solution to at least the photosensitive layer coated side of said plate without developing said plate; and
(d) developing said treated plate with ink and/or fountain solution on a lithographic press to remove the non-hardened or solubilized areas of said photosensitive layer.

27. The method of claim 26 wherein said photosensitive layer is capable of hardening upon exposure to said radiation (negative-working), and said treated plate is developed to remove the non-hardened areas of said photosensitive layer.

28. The method of claim 26 wherein said photosensitive layer is capable of solubilization upon exposure to said radiation (positive-working), and said treated plate is developed to remove the solubilized areas of said photosensitive layer.

29. The method of claim 26 wherein said radiation is a laser having a wavelength selected from 200 to 1200 nm.

30. The method of claim 26 wherein said radiation is a violet or ultraviolet laser having a wavelength selected from 300 to 430 nm.
